(19) United States
(12) Patent Application Publication
(10) Pub. No.: US 2005/0018495 A1
(43) Pub. Date: Jan. 27, 2005

(54) ARRANGEMENT OF INTEGRATED CIRCUITS IN A MEMORY MODULE

(75) Inventors: Jayesh R. Bhakta, Cerritos, CA (US); Robert S. Pauley, San Juan Capistrano, CA (US); William M. Gervasi, Los Gatos, CA (US)

Correspondence Address: KNOBBE MARTENS OLSON & BEAR LLP, 2040 MAIN STREET, FOURTEENTH FLOOR, IRVINE, CA, 92614, US

(73) Assignee: Netlist, Inc., Irvine, CA (US)

(21) Appl. No.: 10/769,469

(22) Filed: Jan. 29, 2004

Related U.S. Application Data
(63) Continuation-in-part of application No. 10/094,512, filed on Mar. 7, 2002.

(51) Int. Cl. G11C 7/00

(52) U.S. Cl. 365/199

(57) ABSTRACT

Abstract of the Disclosure

Integrated circuits utilizing standard commercial packaging are arranged on a printed circuit board to allow the production of one-Gigabyte, two-Gigabyte, and four-Gigabyte capacity memory modules. A first row of integrated circuits is oriented in an opposite orientation to a second row of integrated circuits. The integrated circuits in the first row on a first lateral portion of the printed circuit board and in the second row on the first lateral portion are connected to a first addressing register with two register integrated circuits. The integrated circuits in the first row on the second lateral portion and in the second row on the second lateral portion are connected to a second addressing register with two register integrated circuits. Each addressing register processes a non-contiguous subset of the bits in each data word.

### Detailed Description of the Invention

### Cross Reference to Related Applications

This application is a continuation-in-part of U.S. Patent Application No. 10/094,512, filed March 7, 2002, the disclosure of which is incorporated in its entirety by reference herein. This application also claims priority to U.S. Provisional Patent No. 60/516,684, filed November 3, 2003, the disclosure of which is incorporated in its entirety by reference herein. This application is related to the following co-pending applications: U.S. Patent Application No. 10/674,240, filed September 29, 2003; U.S. Patent Application No. 10/674,082, filed September 29, 2003; U.S. Patent Application No. 10/765,488 filed on January 27, 2004; and U.S. Patent Application No. 10/765,420 filed on January 27, 2004. Each of these co-pending applications is a divisional of U.S. Patent Application No. 10/094,512, filed March 7, 2002, and each of these co-pending applications is incorporated in its entirety by reference herein. This application is also related to U.S. Patent Application No. 10/768,534, filed on January 30, 2004, which is a continuation of U.S. Patent Application No. 10/094,512, filed on March 7, 2002.

### Background of Invention

### Field of the Invention

The present invention relates to memory modules for use in computers. More specifically, the invention relates to the layout and organization of integrated circuits to achieve predetermined memory capacity.

### Description of the Related Art

The demand for high speed, high capacity memory modules for use in the computer industry has grown rapidly. The average base memory capacity of servers recently increased from one-Gigabyte to four-Gigabytes. The cost of dynamic random access memory (DRAM) modules declined by more than 75%.

To successfully operate in a computer, a memory module must meet standard timing and interface requirements for the type of memory module intended for use in the particular computer. These requirements are defined in design specification documents that are published by either the original initiator of the standard (e.g., Intel or IBM) or a standards issuing body such as JEDEC (formerly, the Joint Electron Device Engineering Council). Among the most important design guidelines for memory module manufacturers are those for synchronous dynamic random access memory (SDRAM), such as PC SDRAM, PC133 SDRAM, DDR SDRAM, and DDR2 SDRAM. The requirements documents also provide design guidelines which, if followed, will result in a memory module that meets the necessary timing requirements.

To meet the requirements defined in the SDRAM design guidelines and respond to consumer demand for higher capacity memory modules, manufacturers of memory modules have attempted to place a higher density of memory integrated circuits on boards that meet the board height guidelines (e.g., 1.25, 1.75, or 30mm) found in the design specifications. Achieving the effective memory density on the printed circuit board has presented a substantial challenge to memory module manufacturers. High memory density on the memory module board has previously been achieved via the use of stacked integrated circuits.

Stacking a second layer of integrated circuits on top of the integrated circuits directly on the surface of the printed circuit board allows the manufacturer to double the memory density on the circuit board. However, the stacking of integrated circuits results in twice as much heat generation as with single layers of integrated circuits, with no corresponding increase in surface area. Consequently, memory modules using stacked integrated circuits have substantial disadvantages over memory modules using a single layer of integrated circuits. Operating at higher temperatures increases the incidence of bit failure. Greater cooling capacity is needed to avoid the problems of high temperature operation. Thermal fatigue and physical failure of the connections between the circuit board and the integrated circuit can result from ongoing heating and cooling cycles.

### Summary of Invention

Certain embodiments provide a memory module comprising a printed circuit board comprising a first lateral portion and a second lateral portion. The memory module further comprises a first plurality of memory integrated circuits identical to one another. The first plurality of memory integrated circuits is positioned on the first lateral portion of the printed circuit board. The memory module further comprises a second plurality of memory integrated circuits identical to one another and identical to the memory integrated circuits of the first plurality. The second plurality of memory integrated circuits is positioned on the second lateral portion of the printed circuit board. The memory module further comprises a first register integrated circuit coupled to the first plurality of memory integrated circuits and a second register integrated circuit coupled to the first plurality of memory integrated circuits. The memory module further comprises a third register integrated circuit coupled to the second plurality of memory integrated circuits and a fourth register integrated circuit coupled to the second plurality of memory integrated circuits. In certain such embodiments, the memory integrated circuits comprise DDR2 SDRAM integrated circuits.

Certain embodiments provide a memory module comprising a generally planar printed circuit board comprising an edge, a common signal trace connector area along the edge, and a first side. The printed circuit board has a first lateral portion and a second lateral portion. The memory module further comprises a first row of memory integrated circuits identical to one another. The first row is positioned on the first side of the printed circuit board. The first row is in proximity to the common signal trace connector area. The integrated circuits of the first row have a first orientation direction. The first row has a first number of integrated circuits on the first lateral portion and a second number of integrated circuits on the second lateral portion. The first number is larger than the second number. The memory module further comprises a second row of memory integrated circuits identical to the integrated circuits of the first row. The second row is positioned on the first side of the printed circuit board. The second row is located physically farther from the common signal trace connector than is the first row. The integrated circuits of the second row have a second orientation direction at a non-zero angle relative to the first orientation direction. The second row has a third number of integrated circuits on the first lateral portion and a fourth number of integrated circuits on the second lateral portion. The third number is larger than the fourth number. The memory module further comprises a first addressing register comprising two register integrated circuits. The first addressing register is coupled to the integrated circuits of the first row on the first lateral portion and is coupled to the integrated circuits of the second row on the first lateral portion. The memory module further comprises a second addressing register comprising two register integrated circuits. The second addressing register is coupled to the integrated circuits of the first row on the second lateral portion and coupled to the integrated circuits of the second row on the second lateral portion.

Certain embodiments provide a memory module comprising a generally planar printed circuit board. The printed circuit board comprises an edge, a common signal trace connector area along the edge, and a first side. The printed circuit board has a first lateral portion and a second lateral portion. The memory module further comprises a first row of memory integrated circuits identical to one another. The first row is positioned on the first side of the printed circuit board and is in proximity to the common signal trace connector area. The integrated circuits of the first row have a first orientation direction. The first row has a first number of integrated circuits on the first lateral portion and a second number of integrated circuits on the second lateral portion. The first number is larger than the second number. The memory module further comprises a second row of memory integrated circuits identical to the integrated circuits of the first row. The second row is positioned on the first side of the printed circuit board. The second row is located physically farther from the common signal trace connector than is the first row. The integrated circuits of the second row have a second orientation direction at a non-zero angle relative to the first orientation direction. The second row has a third number of integrated circuits on the first lateral portion and a fourth number of integrated circuits on the second lateral portion. The third number is larger than the fourth number. The memory module further comprises a first addressing register comprising at least one register integrated circuit. The first addressing register is coupled to the integrated circuits of the first row on the first lateral portion and is coupled to the integrated circuits of the second row on the first lateral portion. The memory module further comprises a second addressing register comprising at least one register integrated circuit. The second addressing register is coupled to the integrated circuits of the first row on the second lateral portion and is coupled to the integrated circuits of the second row on the second lateral portion.

Certain embodiments provide a onecapacity memory module comprising 36 integrated circuits. The integrated circuits are 256-Megabit SDRAM organized as 64 Meg by 4 bits. The integrated circuits are in a Ball Grid Array (BGA) package. The memory module has an approximate width of five-and-one-fourth (5¼) inches (133.35 mm) and an approximate height of one-and-one-half (1½) inches (38 mm).

Certain embodiments provide a twocapacity memory module comprising 36 integrated circuits. The integrated circuits are 512-Megabit SDRAM organized as 128 Meg by 4 bits. The integrated circuits are in a Ball Grid Array (BGA) package. The memory module has an approximate width of five-and-one-fourth (5¼) inches (133.35 mm) and an approximate height of one-and-one-half (1½) inches (38 mm).

Certain embodiments provide a fourcapacity memory module comprising 36 integrated circuits. The integrated circuits are 1024-Megabit SDRAM organized as 256 Meg by 4 bits. The integrated circuits are in a Ball Grid Array (BGA) package. The memory module has an approximate width of five-and-one-fourth (5¼) inches (133.35 mm) and an approximate height of one-and-one-half (1½) inches (38 mm).

Certain embodiments provide a memory module comprising a printed circuit board and a plurality of identical integrated circuits. The integrated circuits are mounted on one or both sides of the printed circuit board in first and second rows. The integrated circuits in the first row on a side are oriented in an opposite orientation from the integrated circuits in the second row on the same side. The orientation of the integrated circuits are indicated by an orientation indicia contained on each integrated circuit.

Certain embodiments provide a memory module comprising a printed circuit board. A plurality of identical integrated circuits are mounted in two rows on at least one side of the printed circuit board. The memory module also includes a control logic bus, a first register and a second register. The control logic bus is connected to the integrated circuits. The first register and the second register are connected to the control logic bus. Each row of integrated circuits is divided into a first lateral half and a second lateral half. The first register addresses the integrated circuits in the first lateral half of both rows. The second register addresses the integrated circuits in the second lateral half of both rows.

Certain embodiments provide a memory module comprising a printed circuit board. A plurality of identical integrated circuits are mounted in two rows on at least one side of the printed circuit board. The memory module includes a control logic bus, a first register and a second register. The control logic bus is connected to the integrated circuits. The first register and the second register are connected to the control logic bus. The first register accesses a first range of data bits and a second range of data bits. The second register accesses a third range of data bits and a fourth range of data bits. The first range of data bits and the second range of data bits are non-contiguous subsets of a data word. The third range of data bits and the fourth range of data bits are also non-contiguous subsets of a data word.

Certain embodiments provide a method for arranging integrated circuit locations on a printed circuit board. The method comprises placing locations for the integrated circuits in a first row and a second row onto at least one surface of a printed circuit board. The integrated circuit locations in the second row are oriented 180 degrees relative to an orientation of the integrated circuit locations in the first row.

Certain embodiments provide a method for the manufacture of memory modules. The method comprises placing the locations for the integrated circuits on a printed circuit board in a first row and a second row on at least one side of the printed circuit board, and orienting the integrated circuit locations in the first row 180 degrees relative to the orientation of the integrated circuits in the second row. The method further comprises interconnecting the integrated circuit locations in a first half of the first row of integrated circuits and the first half of the second row of integrated circuits to a first register location, and interconnecting the integrated circuit locations in a second half of the first row of integrated circuit locations and the second half of the second row of integrated circuit locations to a second register location. The method also comprises placing identical integrated circuits at the integrated circuit locations in the printed circuit board.

Certain embodiments provide a onecapacity memory module comprising 36 integrated circuits. The integrated circuits are 256-Megabit (i.e., 268,435,456 bits) SDRAM organized as 64 Meg by 4 bits (i.e., 67,108,864 addressed locations with 4 bits per location). The integrated circuits are in a Thin Small Outline Package (TSOP). The memory module has an approximate width of 5.25 inches (133.350 mm) and an approximate height of 2.05 inches (52.073 mm).

Certain embodiments provide a twocapacity memory module comprising 36 integrated circuits. The integrated circuits are 512-Megabit (i.e., 536,870,912 bits) SDRAM organized as 128 Meg by 4 bits (i.e., 134,217,728 addressed locations with 4per location). The integrated circuits are in a Thin Small Outline Package (TSOP). The memory module has an approximate width of 5.25 inches (133.350 mm) and an approximate height of 2.05 inches (52.073 mm).

Certain embodiments provide a four-Gigabyte capacity memory module comprising 36 integrated circuits. The integrated circuits are 1-Gigabit (i.e., 1,073,741,824 bits) SDRAM organized as 256 Meg by 4 bits (i.e., 268,435,456 addressed locations with 4 bits per location). The integrated circuits are in a Thin Small Outline Package (TSOP). The memory module has an approximate width of 5.25 inches (133.35 mm) and an approximate height of 2.05 inches (52.073 mm).

### Brief Description of Drawings

The accompanying drawings are included to provide a further understanding of embodiments of the present invention and are incorporated in and constitute a part of this specification. The drawings illustrate embodiments of the present invention and, together with the description, serve to explain the principles of the invention.

FIGURE 1A illustrates a view of the primary side of a memory module in an embodiment of a PC133 SDRAM memory module.

FIGURE 1B illustrates a view of the secondary side of the memory module of FIGURE 1A.

FIGURE 2A illustrates a view of the primary side of a memory module in an embodiment of a DDR SDRAM memory module.

FIGURE 2B illustrates a view of the secondary side of the memory module of FIGURE 2A.

FIGURE 3A is a block diagram of an embodiment of a PC 133 SDRAM memory module.

FIGURE 3B is an enlargement of one portion of the block diagram of FIGURE 3A.

FIGURE 4A illustrates a portion of the primary signal layer of a printed circuit board in an embodiment of a memory module.

FIGURE 4B illustrates a portion of the MID1 layer of a printed circuit board in an embodiment of a memory module.

FIGURE 4C illustrates a portion of the MID2 layer of a printed circuit board in an embodiment of a memory module.

FIGURE 5A illustrates a first side of an embodiment of a non-bilaterally symmetric memory module utilizing DDR2 SDRAM integrated circuits with an approximate thickness T of 3.57 millimeters (0.141 inches), an approximate height H of 38 millimeters (1.496 inches), and an approximate width W of 133.35 millimeters (5.25 inches).

FIGURE 5B illustrates a second side of the embodiment of FIGURE 5A.

FIGURE 6A illustrates a block diagram of an embodiment of a DDR2 SDRAM memory module.

FIGURE 6B illustrates a first portion of the upper row of the block diagram shown in FIGURE 6A.

FIGURE 7A illustrates a first side of another non-bilaterally symmetric memory module utilizing DDR2 SDRAM integrated circuits.

FIGURE 7B illustrates a second side of the embodiment of FIGURE 7A.

FIGURE 8A illustrates an exemplary connection scheme for the addressing registers of one embodiment of a 1-Gb memory module using DDR2 SDRAM integrated circuits and having a first addressing register comprising two register integrated circuits and a second addressing register comprising two register integrated circuits.

FIGURE 8B illustrates an exemplary connection scheme for a clock integrated circuit for a 1memory module using DDR2 SDRAM integrated circuits.

FIGURE 9 illustrates an exemplary connection scheme for an edge connector for a 1-Gb memory module using DDR2 SDRAM integrated circuits.

FIGURE 10A illustrates an exemplary connection scheme for the first row of DDR2 SDRAM integrated circuits for a 1-Gb memory module.

FIGURE 10B illustrates an exemplary connection scheme for the second row of DDR2 SDRAM integrated circuits for a 1-Gb memory module.

FIGURE 10C illustrates an exemplary connection scheme for the third row of DDR2 SDRAM integrated circuits for a 1-Gb memory module.

FIGURE 10D illustrates an exemplary connection scheme for the fourth row of DDR2 SDRAM integrated circuits for a 1-Gb memory module.

FIGURES 11A-11G illustrate an exemplary routing diagram for seven layers of a 1-Gb memory module using DDR2 SDRAM integrated circuits.

FIGURE 12A schematically illustrates the signal paths from a selected register solder ball of the BGA of the first register integrated circuit of the first addressing register to the integrated circuits of the first row on the first lateral portion.

FIGURE 12B schematically illustrates the signal paths from a selected register solder ball of the BGA of the first register integrated circuit of the second addressing register to the integrated circuits of the first row on the second lateral portion.

FIGURE 13A schematically illustrates an embodiment using traditional surface-mounted resistors in proximity to the integrated circuit.

FIGURE 13B schematically illustrates an embodiment utilizing an embedded resistor positioned beneath the integrated circuit.

FIGURE 14 schematically illustrates embedded damping resistors located close to the solder ball along the signal path from the edge connectors.

FIGURE 15 schematically illustrates embedded resistors near the point of branching and near the contact to the connector.

FIGURE 16 schematically illustrates a preferred line termination for differential signal path pairs located directly under the solder balls.

FIGURE 17 schematically illustrates a differential signal path pair terminated with embedded resistors at critical points, such as branches, in addition to the line end termination.

FIGURE 18A schematically illustrates an embodiment utilizing surface-mounted capacitors for supply voltage decoupling without load matching.

FIGURE 18B schematically illustrates an embodiment utilizing embedded decoupling capacitors and embedded load matching capacitors.

FIGURE 19 schematically illustrates an embodiment of an embedded flux capacitor with a filtered line using discrete inductors and capacitors.

### Detailed Description

The following description refers to the accompanying drawings, which show, by way of illustration, specific embodiments in which the invention may be practiced. Numerous specific details of these embodiments are set forth in order to provide a thorough understanding of the invention. However, it will be apparent to one skilled in the art that the invention may be practiced without the specific details or with certain alternative components and methods to those described herein.

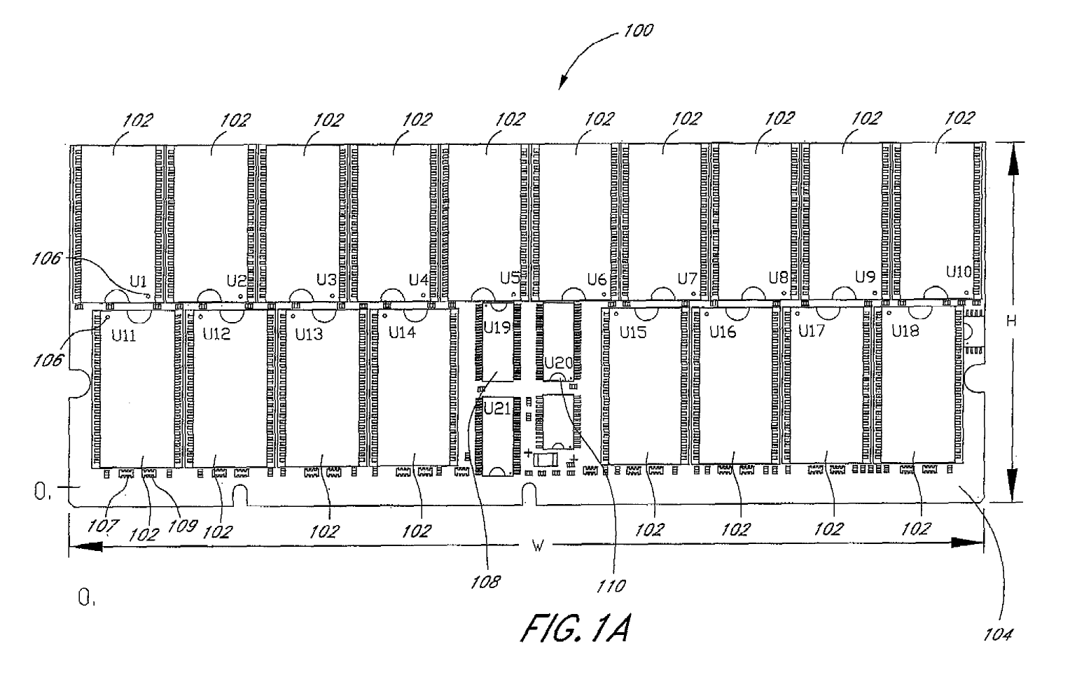

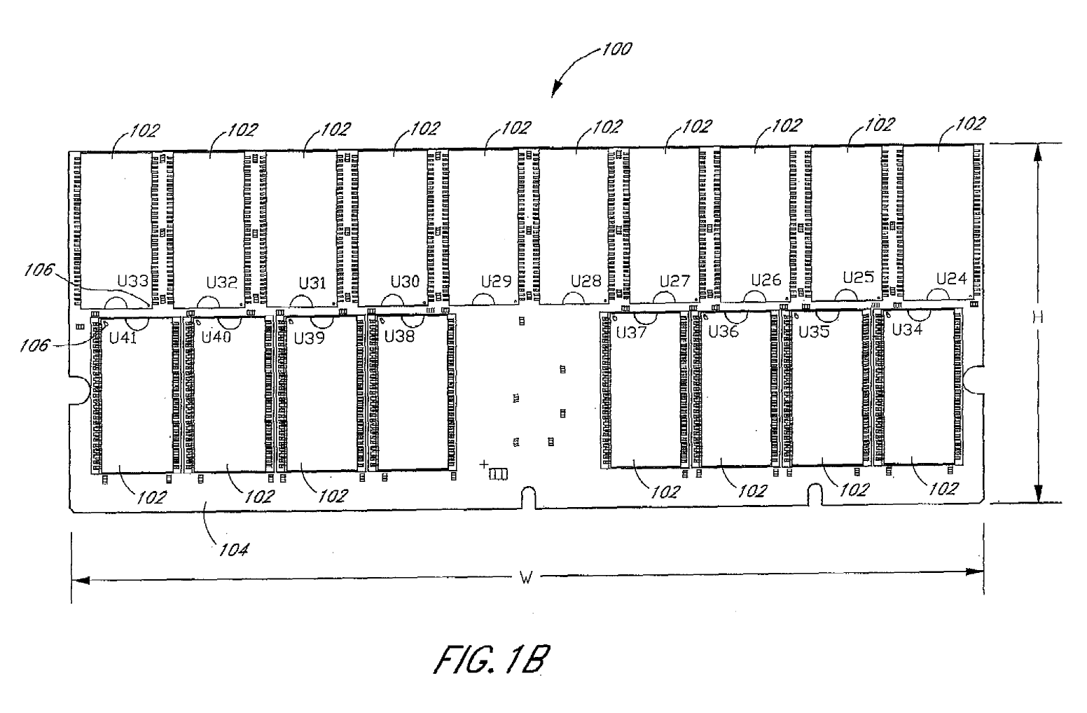

FIGURE 1A illustrates the primary side of an embodiment of a memory module 100 utilizing PC133 SDRAM integrated circuits. The module 100 comprises two rows of memory integrated circuits 102 mounted onto a printed circuit board 104. The memory module 100 meets the timing standards for and is compatible with JEDEC requirements for a PC133 SDRAM module, but departs from the design guidelines contained in the PC133 design specification. In particular, the memory module 100 meets the timing and interface requirements of the PC133 standard notwithstanding the module 100 having a height (H) of approximately two inches. This height exceeds the 1.75 height guideline recommended in the PC133 Design Specification, but allows a single layer of conventional TSOP integrated circuits 102 to be placed in two rows on each side of the printed circuit board 104, thus avoiding the negative characteristics caused by stacking of integrated circuits and also avoiding the use of more expensive micro-BGA integrated circuits. The printed circuit board maintains a width (W) of 5.25 as defined in the PC133 Design Specification.

In certain embodiments, the memory module 100 is compatible with the timing requirements while using a greater printed circuit board height through the unique layout and arrangement of the integrated circuits 102 on the printed circuit board and the arrangement of integrated circuit interconnections. In certain embodiments, the integrated circuits 102 (designated U1 through U10) of the upper row have an orientation direction at a non-zero angle relative to an orientation direction of the integrated circuits 102 (designated U11 through U18) of the lower row. The orientation direction of the integrated circuits 102 of the upper row is rotated in a plane parallel to the printed circuit board by the non-zero angle from the orientation direction of the integrated circuits 102 of the lower row. As illustrated in FIGURE 1A, in certain embodiments, the non-zero angle is approximately 180 degrees, such that the integrated circuits 102 of the upper row are oriented in the opposite direction from the integrated circuits 102 of the lower row. Other non-zero angles, either positive or negative, are also compatible with embodiments described herein.

FIGURE 1B illustrates the second side of an embodiment of a memory module 100. The integrated circuits 102 (designated U24 through U33) of the upper row on the second side of the printed circuit board 104 are placed in an orientation at a non-zero angle relative to an orientation of the integrated circuits 102 (designated U34 through U41) of the lower row. The orientation direction of the integrated circuits 102 of the upper row is rotated in a plane parallel to the printed circuit board by the non-zero angle from the orientation direction of the integrated circuits 102 of the lower row. As illustrated in FIGURE 1B, in certain embodiments, the non-zero angle is approximately 180 degrees, such that the integrated circuits 102 of the upper row are oriented in the opposite direction from the integrated circuits 102 of the lower row. Other non-zero angles, either positive or negative, are also compatible with embodiments described herein. The orientation of each integrated circuit 102 can be advantageously determined from an orientation indicia 106. For example in the illustrated embodiment, the orientation indicia is a small circular mark 106 on the surface of the integrated circuit 102.

In certain embodiments, the different orientations of the upper row of integrated circuits 102 and the lower row of integrated circuits 102 allow the traces on the signal layer of the memory module 100 to be placed such that the trace lengths to the data pins on the integrated circuits 102 in the first (upper) row have substantially the same length as the signal traces to the data pins on the integrated circuits 102 in the second (lower) row.

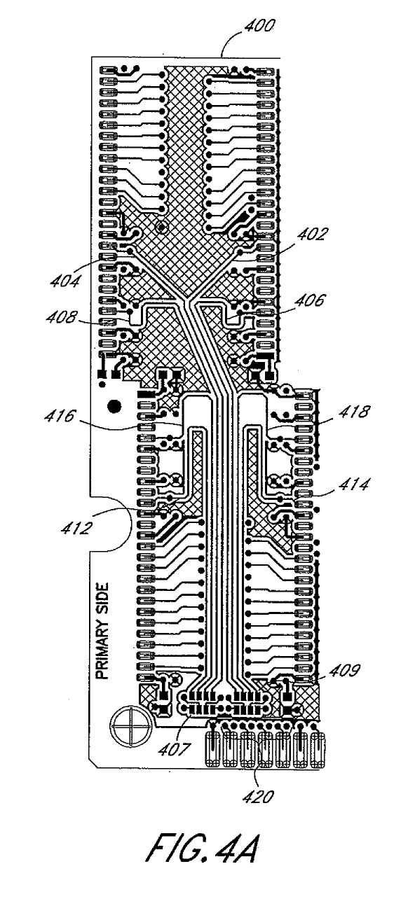

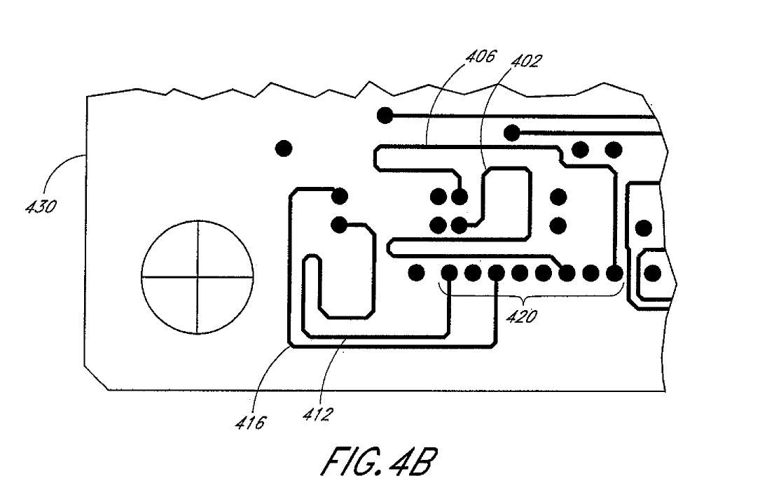

FIGURE 4A illustrates a portion of a primary signal layer 400 of the printed circuit board 104 of the embodiment of a memory module 100 illustrated in FIGURE 1A and 1B. FIGURE 4B illustrates a portion of a MID1 signal layer 430 of the printed circuit board 104 of the embodiment of a memory module illustrated in FIGURE 1A and 1B. Figure 4C illustrates a portion of a MID2 signal layer 460 of the embodiment of a memory module illustrated in FIGURE 1A and 1B.

The illustrated portion of the primary signal layer 400 connects to the integrated circuits 102 designated U1 and U11. A signal trace 404 to one of the data pins of the U1 integrated circuit is designed to have substantially the same length from the data pin of the U1 integrated circuit to the primary memory module connector 420 as the length of a signal trace 414 from the corresponding data pin in the U11 integrated circuit to the primary memory module connector 420. The signal trace 404 from the U1 integrated circuit to the primary memory module connector 420 and the signal trace 414 from the U11 integrated circuit to the primary memory module connector 420 each includes a respective portion of signal trace located on the MID2 layer 460 of the printed circuit board 104, as illustrated in FIGURE 4C. Similarly, a signal trace 408 from a second data pin on the U1 integrated circuit to the primary memory module connector 420 is designed to be of substantially the same length as the length of a signal trace 418 from the corresponding pin on the U11 integrated circuit to the primary memory module connector 420. As illustrated in FIGURE 4C, the signal traces 408, 418 also include respective portions of the traces located on the MID2 layer 460 of the printed circuit board 104.

A signal trace 402 and a signal trace 406 from third and fourth data pins on the U1 integrated circuit to the primary memory module connector 420 are designed to be substantially the same lengths as the lengths of a signal trace 412 and a signal trace 416 from the corresponding data pins on the U11 integrated circuit to the primary memory module connector 420. As illustrated in FIGURE 4B, the signal traces 402, 406, 412, 416 include a portion of the signal trace located on the MID1 layer 430 of the printed circuit board 104.

As shown in FIGURE 1A, in certain embodiments, four signal traces 404, 408, 416, 418 include respective resistors 107 affixed to a first set of connection points 407 (FIGURE 4A) on the primary signal layer 400 of the printed circuit board 104. As further shown in FIGURE 1A, in certain embodiments, the four signal traces 402, 406, 418, 414 include respective resistors 109 (FIGURE 4A) affixed to a second set of connection points 409 on the primary signal layer 400 of the printed circuit board 104. The resistors 107, 109 complete the circuit paths from the integrated circuit pins to the connector 420 and also provide impedance matching required in the JEDEC standards.

The substantially equal signal trace lengths are repeated for each pair of integrated circuit locations in the first and the second row. In certain embodiments, reversing the orientation of the integrated circuits 102 from the first row to the second row (e.g., 180 degrees between the orientations) enables the portions of the signal traces on the primary signal layer 400 serving an integrated circuit in the first row to have substantially the same lengths as the signal traces serving a corresponding integrated circuit in the second row. In other embodiments, other non-zero angles, either positive or negative, between the orientations of the first and second rows are compatible with signal traces having substantially the same lengths to the integrated circuits of the first and second rows. The overall lengths of the traces are configured in certain embodiments to be substantially equal (to within 10% of the total trace length) by varying the lengths of the portions of the traces located on the MID1 layer 430 and the MID2 layer 460. In addition to the data signal trace lengths, the data mask trace lengths and the clock trace lengths advantageously are maintained to be substantially equal in certain embodiments.Unlike known memory module circuit board designs, the substantial equality of trace lengths is achieved in such embodiments without requiring the addition of repetitious back-and-forth (i.e., serpentine) trace portions to the signal traces of the physically closer integrated circuits 102 to equalize the trace lengths of the signal lines of the closer integrated circuits 102 with the trace lengths of the signal lines of the integrated circuits 102 that are located physically farther from a common signal trace connector area 420. Since printed circuit board 104 space is not consumed with serpentine signal traces, the signal traces in certain embodiments are advantageously wider, and the spacing between signal traces in certain embodiments is advantageously greater. The greater width and spacing of the signal traces advantageously results in decreased signal noise and interference in certain embodiments. The absence of serpentine signal traces advantageously results in a memory module 100 that produces less radio frequency interference and is less susceptible to radio frequency interference in certain embodiments.

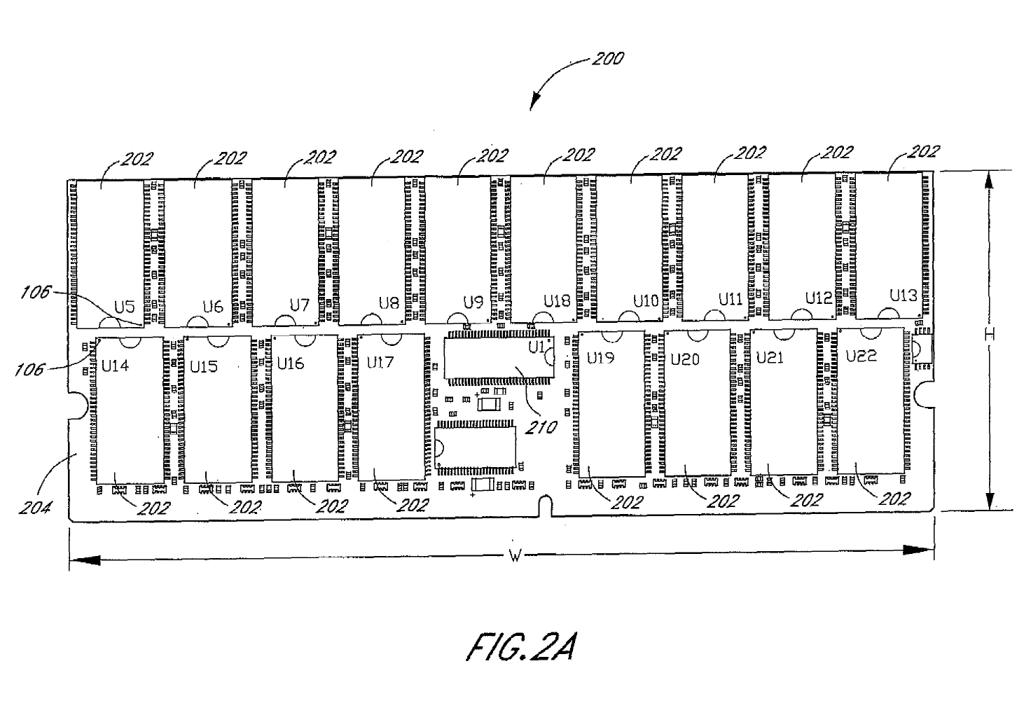

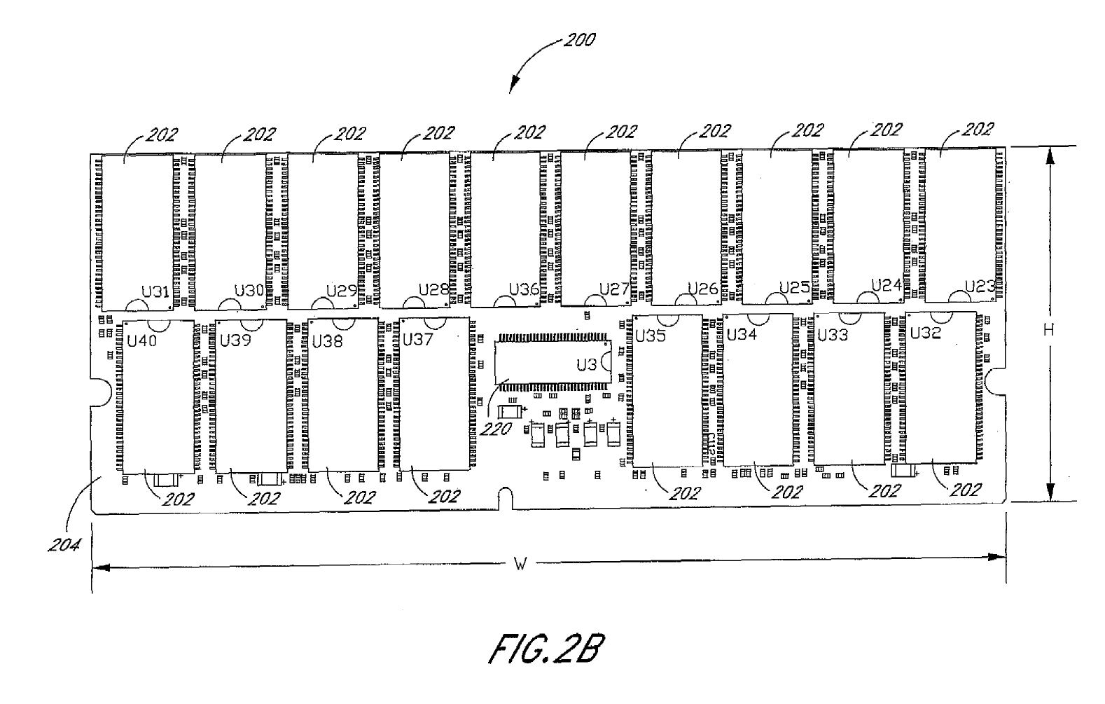

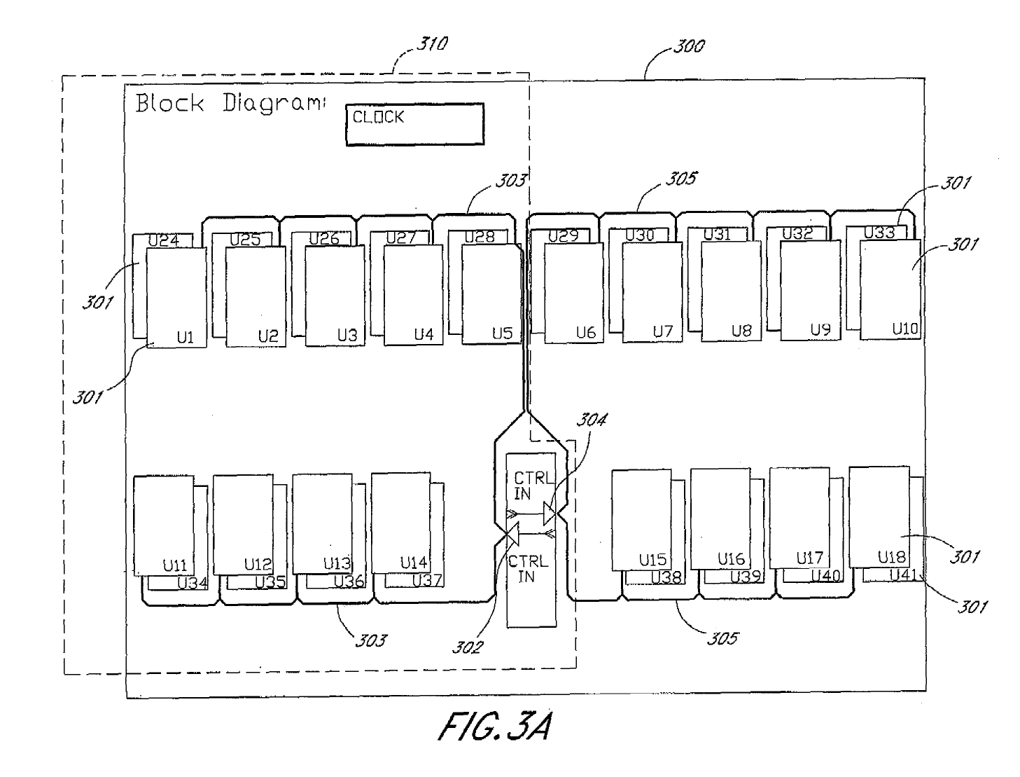

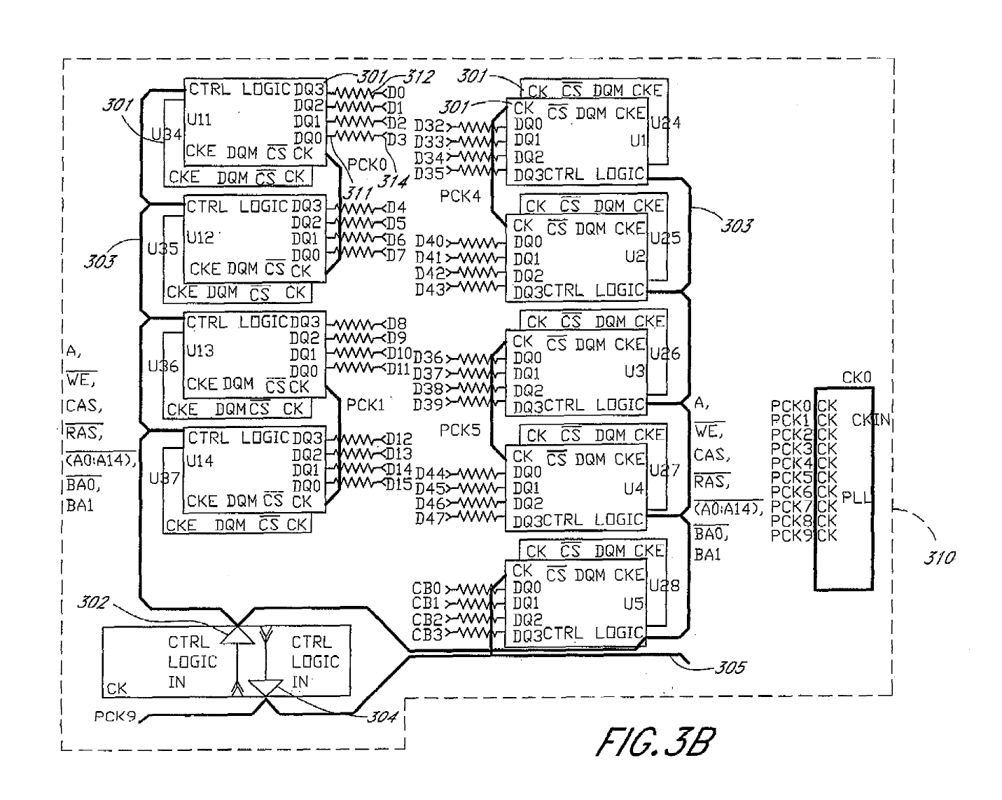

The timing requirements for the memory module 100 are advantageously met in certain embodiments through the use of a second level of symmetry in addition to the use of substantially equal trace lengths. As shown in the block diagram FIGURE 3A, in certain embodiments, the address signals to the integrated circuits 102 in the top and bottom row (integrated circuits designated U1 - U5, U24 - U28, U11 - U14, and U34 - U37) on a first portion of the memory module 100 are routed from a common register 302 via a set 303 of signal paths. The address signals to the integrated circuits 102 on a second portion of the memory module 100 (designated U6 - U10, U29 - U33, U15 - U18, and U38 - U41) are routed from a common register 304 via a second set 305 of signal paths. In certain embodiments in which the first portion comprises one half of the memory module 100 and the second portion comprises the other half of the memory module 100, the integrated circuits are arranged in a bilaterally symmetric configuration, as illustrated in FIGURES 1A, 1B, 2A, and 2B. The use of the bilateral symmetry in such embodiments allows closer matching of timing performance for the signals from the integrated circuits 102, improves the timing performance, and provides greater performance timing margins than traditional design guidelines in which each integrated circuit in a row of integrated circuits 102 is connected to a single register. The operation of the memory module 100 is synchronized with an external clock signal (not shown) from a computer (not shown) by a clock generator circuit 309, which is discussed in more detail below in connection with Figure 3B.

FIGURE 3B illustrates a half 310 of the block diagram shown in FIGURE 3A. As shown in FIGURE 3B, in certain embodiments, the bilateral symmetry utilizes non-contiguous ranges of data bits for each addressing register. Rather than handling the bits in contiguous ranges such as bits 0-31 addressed in a first register and bits 32-63 addressed in a second register, as described in the JEDEC design guidelines, the first register 302 of such embodiments addresses data bits 0-15 (designated D0 through D15) and data bits 32-47 (designated D32 through D47). The second register 304 of such embodiments addresses the integrated circuits 102 on the other half of the block diagram (not shown in FIGURE 3B), which store data bits 16-31 and bits 48-63. Each data bit (designated D0 through D63) and each check bit (designated CB0 through CB7) connects to the memory module connection interface 314 via a respective signal trace 311 which contains a respective resistive element 312. The resistive elements 312 in FIGURE 3B correspond to the resistors 107, 109 in FIGURE 1A. The physical layout of the signal traces 311 of certain embodiments is illustrated in FIGURES 4A through 4C. Although the data word of such embodiments is assembled from the bits addressed by both registers, the use of non-contiguous portions of the data word in such embodiments advantageously allows the use of a symmetric layout of the memory module 100 that complies with memory module timing requirements on a physically larger board than envisioned in the design guidelines. In certain embodiments, the use of bilateral symmetry in the board layout and the use of non-contiguous bit ranges is advantageously usable for larger data word lengths than the 64-bit word length given in this embodiment.

In certain embodiments, the operation of the memory integrated circuits U1-U18, U24-U41 and the operation of the common registers 302, 304 are controlled by a plurality of clock signals PCK0-PCK9 from the clock generator circuit 309. The clock generator circuit 309 includes a phase locked loop (PLL) (not shown) that operates in a conventional manner to synchronize the clock signals with an input clock signal (CKIN) from the computer (not shown) or other system into which the memory module is inserted. Each of the clock signals PCK0-PCK8 is connected to four memory integrated circuits, and the clock signal PCK9 is connected to the common registers 302, 304. In the illustrated embodiment, the clock signals are connected to the memory integrated circuits and the common registers as follows (only the connections to the circuits shown in FIGURE 3B are illustrated):

| | | |
|---|---|---|
| PCK0 | U11, U12, U34, U35 | (D0-D3, D4-D7) |
| PCK1 | U13, U14, U36, U37 | (D8-D11, D12-D15) |
| PCK2 | U15, U16, U38, U39 | (D16-D19, D20-D23) |
| PCK3 | U17, U18, U40, U41 | (D24-D27, D28-D31) |
| PCK4 | U1, U2, U24, U25 | (D32-D35, D40-D43) |
| PCK5 | U3, U4, U26, U27 | (D36-D39, D44-D47) |
| PCK6 | U1, U2, U24, U25 | (D48-D51, D52-D55) |
| PCK7 | U9, U10, U32, U33 | (D56-D59, D60-D63) |
| PCK8 | U5, U6, U28, U29 | (CB0-CB3, CB4-CB7) |
| PCK9 | control registers 302, 304 | |

As shown in FIGURE 1B, in certain embodiments, the integrated circuits 102 are advantageously mounted on both sides of the printed circuit board 104. The mounting of integrated circuits 102 on both sides of the printed circuit board, and the use of bilateral symmetry of the signal traces on the printed circuit board in certain embodiments advantageously permits the use of a larger printed circuit board and standard memory integrated circuits 102. The integrated circuits 102 used in certain embodiments are advantageously commercially available 64 Meg by 4-bit (67,108,864 address locations with 4per location) memory integrated circuits for a one-Gigabyte capacity memory module 100 and in other embodiments are advantageously commercially available 128 Meg by 4-bit (134,217,728 addressed locations with 4 bits per location) memory integrated circuits for a two-Gigabyte capacity memory module 100. Because of the location of the data pins of the integrated circuits 102, the four data pins of the integrated circuits 102 on the second side of the printed circuit board 104 in certain embodiments are directly opposite the four data pins of the integrated circuits 102 on the first side of the printed circuit board. Thus, the data pins of the integrated circuits on the opposite sides are serviced by the signal traces shown in FIGURE 4A using a via between the two sides for each signal trace.

An embodiment of a memory module 200 that is compatible with the timing requirements for Double Data Rate (DDR) SDRAM is shown in FIGURE 2A and FIGURE 2B. The DDR SDRAM module 200 comprises memory integrated circuits 202 utilizing standard TSOP packaging. The integrated circuits 202 are compatible with the JEDEC DDR timing requirements. The DDR SDRAM module 200 illustrated by FIGURES 2A and 2B advantageously utilizes bilateral symmetry to achieve the timing requirements specified in the DDR SDRAM requirements on a board 204 having a height (H) of approximately 2 inches and a width (W) of 5.25 inches.

In the embodiments of FIGURES 2A and 2B, the integrated circuits 202 are oriented, as advantageously indicated by an orientation indicia 106, in opposite orientations in a first and a second row, respectively. The trace lengths of signal traces to the integrated circuits 202 in the first (upper) row are maintained to be substantially the same as the signal traces to integrated circuits 202 in the second (lower) row. The integrated circuits 202 mounted to a first half of the memory module 200 are routed to a first register 210 and the integrated circuits 202 mounted to a second half of the memory module 200 are routed to a second register 220. As with the PC133 SDRAM module 100, each data register stores non-contiguous portions of the data word.

### Embodiment with Four Register Integrated Circuits

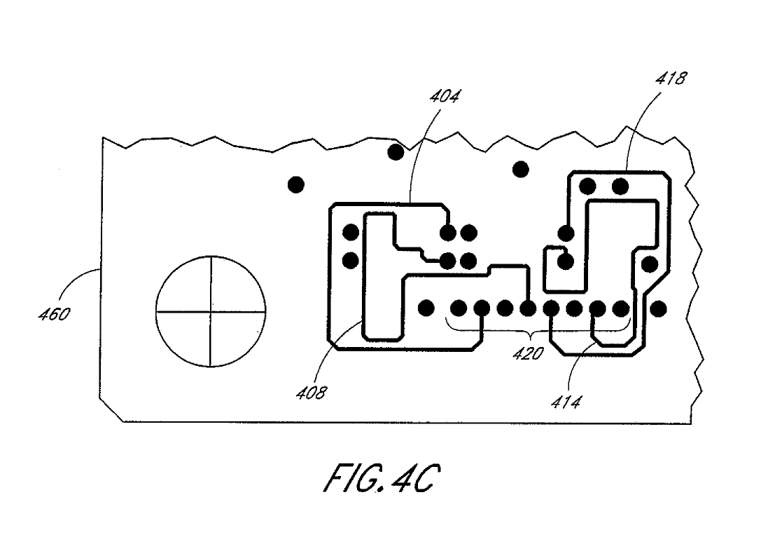

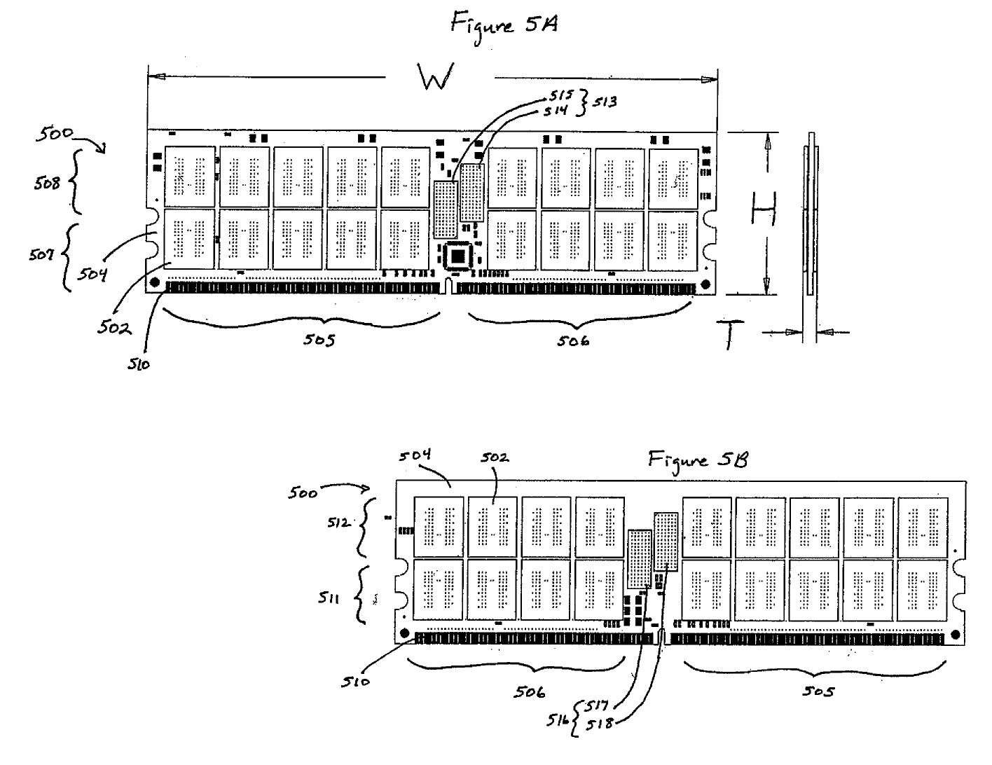

FIGURE 5A illustrates a first side of an embodiment of a non-bilaterally symmetric memory module 500 utilizing DDR2 SDRAM integrated circuits. The module 500 comprises at least two rows of memory integrated circuits 502 mounted onto a printed circuit board 504 with a first lateral portion 505 and a second lateral portion 506. The first row 507 is positioned without bilateral symmetry on the first side of the printed circuit board 504 and is in proximity to the common signal trace connector area 510. The integrated circuits of the first row 507 have a first orientation direction. The first row 507 has a first number (e.g., five) of integrated circuits 502 on the first lateral portion 505 and a second number (e.g., four) of integrated circuits 502 on the second lateral portion 506. The second row 508 is positioned without bilateral symmetry on the first side of the printed circuit board 504 and is located physically farther from the common signal trace connector 510 than is the first row 507. The integrated circuits 502 of the second row 508 have a second orientation direction at a non-zero angle relative to the first orientation direction. The second row 508 has a third number (e.g., five) of integrated circuits 502 on the first lateral portion 505 and a fourth number (e.g., four) of integrated circuits 502 on the second lateral portion 506.

In certain embodiments, one or both of the first row 507 and the second row 508 are substantially parallel to the edge of the printed circuit board 504. In certain embodiments, the first number and the third number are equal (e.g., five), and in other embodiments, the second number and the fourth number are equal (e.g., four). FIGURE 5A schematically illustrates an embodiment in which the first and third numbers equal five, and the second and fourth numbers equal four. Other embodiments can utilize other numbers of integrated circuits in the first row 507 and the second row 508 distributed among the first lateral portion 505 and the second lateral portion 506.

In FIGURE 5A, the BGA pattern of each integrated circuit 502 is shown to illustrate the relative orientations of the integrated circuits 502. The memory module 500 meets the timing standards for and is compatible with JEDEC requirements for a DDR2 SDRAM module. The memory module 500 has a height H of approximately one-and-one-half (1½) inches and a width W of approximately five-and-one-fourth (5¼) inches. As described above in relation to the PC 133 embodiment, the memory module 500 has a unique layout and arrangement of the integrated circuits 502 on the printed circuit board 504 and arrangement of integrated circuit interconnections. In certain embodiments, the integrated circuits 502 of the second row 508 has an orientation direction at a non-zero angle relative to an orientation direction of the integrated circuits 502 of the first row 507. The orientation direction of the integrated circuits 502 of the second row 508 is rotated in a plane parallel to the printed circuit board 504 by the non-zero angle from the orientation direction of the integrated circuits 502 of the first row 507. As illustrated in FIGURE 5A, in certain embodiments, the non-zero angle is approximately 180 degrees, such that the integrated circuits 502 of the second row 508 are oriented in the opposite direction from the integrated circuits 502 of the first row 507. Other non-zero angles, either positive or negative, are compatible with embodiments described herein.

FIGURE 5B illustrates a second side of the embodiment of the memory module 500 with two more rows of integrated circuits 502. The integrated circuits 502 of the third row 511 on the second side of the printed circuit board 504 are placed in an orientation direction at a non-zero angle relative to an orientation direction of the integrated circuits 502 of the fourth row 512. As illustrated in FIGURE 5B, in certain embodiments, the non-zero angle is approximately 180 degrees, such that the integrated circuits 502 of the third row 511 are oriented in the opposite direction from the integrated circuits 502 of the fourth row 512. Other non-zero angles, either positive or negative, are compatible with embodiments described herein.In certain embodiments, as illustrated in FIGURE 5B, the third row 511 and the fourth row 512 of integrated circuits 502 on the second side of the printed circuit board 504 do not have bilateral symmetry with respect to the printed circuit board 504, with each row having different numbers of integrated circuits on the first lateral portion 505 and the second lateral portion 506. For example, as illustrated in FIGURE 5B, each row has five integrated circuits on the first lateral portion 505 and four integrated circuits on the second lateral portion 506.

As described above in relation to the PC133 memory module, the different orientation directions between two rows of the printed circuit board 504 allow the trace lengths to the BGA balls of the integrated circuits 502 in the two rows to be substantially the same. The overall lengths of the traces are configured in certain embodiments to be substantially equal (to within 10% of the total trace length) by varying the lengths of the portions of the traces located on the MID1 layer and the MID2 layer of the printed circuit board 504. In addition to the data signal trace lengths, the data mask trace lengths and the clock trace lengths advantageously are maintained to be substantially equal in certain embodiments.

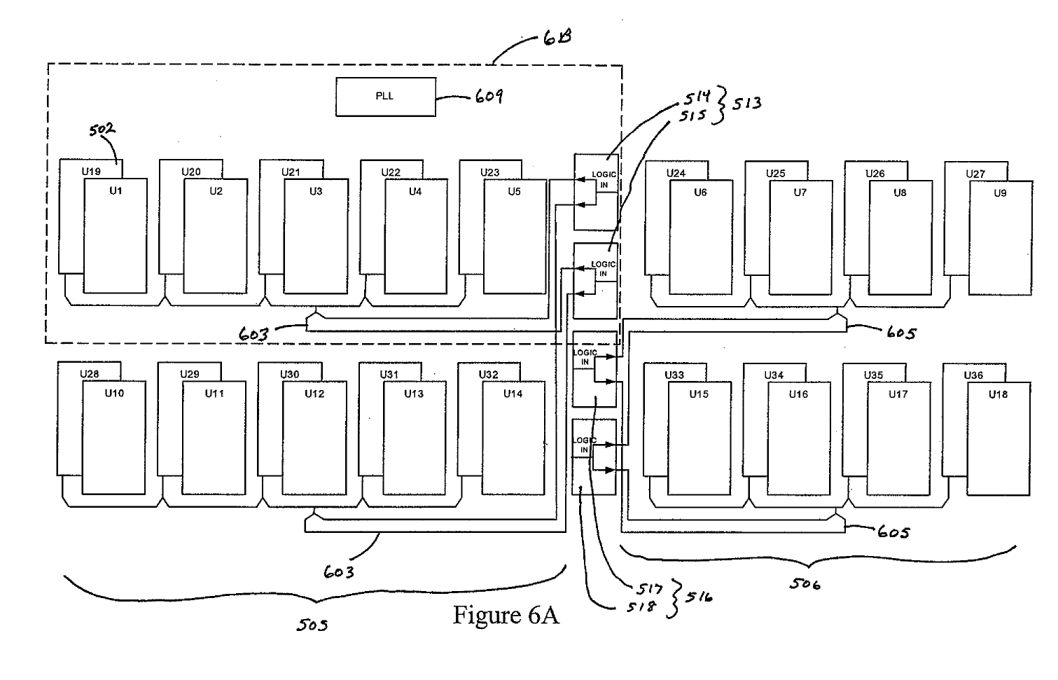

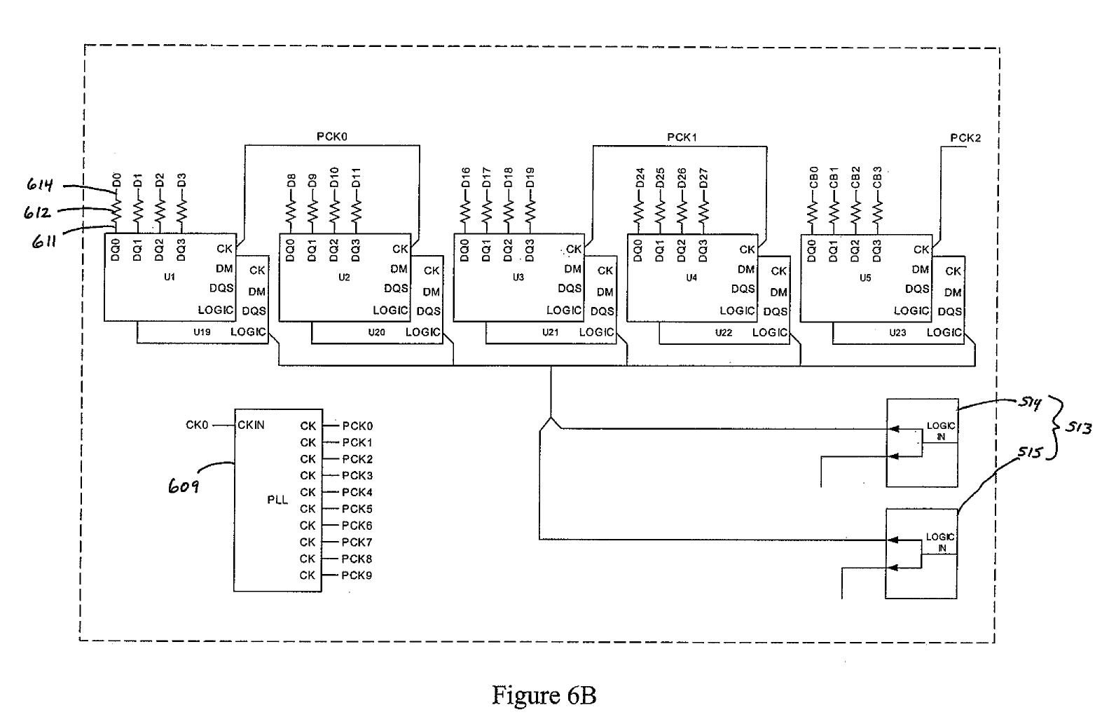

FIGURES 5A and 5B also show an addressing register on each side of the printed circuit board 504. On the first side, the first addressing register 513 comprises a pair of register integrated circuits 514, 515. On the second side, the second addressing register 516 comprises a pair of register integrated circuits 517, 518. As shown in the block diagram of FIGURE 6A, in certain embodiments, the address signals to the integrated circuits 502 on the first lateral portion 505 of the first row 507 and the third row 511 (integrated circuits designated U1 - U5 and U19 - U23) and on the first lateral portion 505 of the second row 508 and the fourth row 512 (integrated circuits designated U10 - U14 and U28 - U32) are routed from the first addressing register 513 comprising the pair of register integrated circuits 514, 515 via a set of signal paths 603. In certain embodiments, the address signals to the integrated circuits 502 on the second lateral portion 506 of the first row 507 and the third row 511 (designated U6 - U9 and U24 - U27) and the address signals to the integrated circuits 502 on the second lateral portion 506 of the second row 508 and the fourth row 512 (designated U15 - U18 and U33 - U36) are routed from the second addressing register 516 comprising the second pair of register integrated circuits 517, 518 via a second set of signal paths 605. The operation of the memory module 500 is synchronized with an external clock signal (not shown) from a computer (not shown) by a clock generator circuit 609, which is discussed in more detail below in connection with Figure 6B.

In certain embodiments, use of the four register integrated circuits 514, 515, 517, 518 advantageously distributes the load of the integrated circuits 502. For example, prior art systems which utilize a single standard register integrated circuit (with one input and two outputs) for 18 memory integrated circuits undergo significant loading which degrades the timing performance of the memory module. However, embodiments described herein using two standard register integrated circuits (thereby providing two inputs and four outputs) for 18 memory integrated circuits (e.g., 10 memory integrated circuits for one register integrated circuit and 8 memory integrated circuits for the other) achieve an approximately 50% reduction in loading and a corresponding improvement in the timing performance of the memory module. Examples of such standard register integrated circuits include, but are not limited to, SN74SSTU32864GKER (with no parity) and SN74SSTU32866GKER (with parity), both from Texas Instruments of Dallas, Texas.

In still other embodiments, custom-designed register integrated circuits can be used to provide the desired timing performance. For example, one custom-designed register integrated circuit with one input and four outputs could be used for the 18 memory integrated circuits. In certain embodiments, such custom-designed register integrated circuits require less area on the printed circuit board than do two standard register integrated circuits, thereby preserving space on the printed circuit board.

FIGURE 6B illustrates the first lateral portion 505 of the first row 507 and the third row 511 of the block diagram shown in FIGURE 6A. Certain embodiments utilize non-contiguous ranges of data bits for each addressing register. As shown in FIGURE 6B, the first addressing register 513 addresses data bits 0-3, 816-19, and 24-27 (designated D0-D3, D8-D11, D16-D19, and D24-D27) and check bits 0-3 (designated CB0-CB3). The first addressing register 513 also addresses the data bits and check bits of the first lateral portion 505 of the second row 508 and the fourth row 512 (not shown in FIGURE 6B). In certain such embodiments, the second addressing register 516 addresses the data bits 4-7, 12-15, 20-23, and 28-31 (designated D4-D7, D12-D15, D20-D23, and D28-D31) of the integrated circuits 502 of the second lateral portion 506 (not shown in FIGURE 6B). Each data bit and each check bit connects to the memory module connection interface 614 via a respective signal trace 611 which contains a respective resistive element 612. Although the data word of such embodiments is assembled from the bits addressed by both addressing registers 513, 516, the use of non-contiguous portions of the data word in such embodiments advantageously complies with memory module timing requirements on a physically larger board than envisioned in the design guidelines. In certain other non-bilaterally symmetric embodiments, the use of non-contiguous bit ranges is advantageously usable for larger data word lengths than the 32-bit word length given in this embodiment.

In certain embodiments, the operation of the memory integrated circuits 502 and the operation of the addressing registers 513, 516 are controlled by a plurality of clock signals PCK0-PCK9 from the clock generator circuit 609. The clock generator circuit 609 includes a phase locked loop (PLL) (not shown) that operates in a conventional manner to synchronize the clock signals with an input clock signal (CKIN) from the computer (not shown) or other system into which the memory module 500 is inserted. In certain embodiments, eight of the clock signals are each connected to four memory integrated circuits 502, and one clock signal is connected to the addressing registers 513, 516.

In certain embodiments, the mounting of integrated circuits 502 on both sides of the printed circuit board 504 advantageously permits the use of a larger printed circuit board and standard memory integrated circuits. In certain embodiments, 36available DDR2 SDRAM integrated circuits are organized as 64 Meg by 4for a one-Gigabyte capacity memory module 500 on a printed circuit board 504 having a height of approximately one-and-one-half (1½) inches (38 mm) and a width of approximately five-and-one-fourth (5¼) inches (133.35 mm). In other embodiments, 36available DDR2 SDRAM integrated circuits are organized as 128 Meg by 4for a two-Gigabyte capacity memory module 500 on a printed circuit board 504 having a height of approximately one-and-one-half (1½) inches (38 mm) and a width of approximately five-and-one-fourth (5¼) inches (133.35 In still other embodiments, advantageously 36available DDR2 SDRAM integrated circuits are advantageously organized as 256 Meg by 4for a four-Gigabyte capacity memory module 500 on a printed circuit board 504 having a height of approximately one-and-one-half (1½) inches (38 mm) and a width of approximately five-and-one-fourth (5¼) inches (133.35 mm). Memory modules with other dimensions (e.g., heights of approximately one inch or less) are compatible with embodiments described herein.

In certain embodiments, the four data pins of the integrated circuits 502 on the second side of the printed circuit board 504 are directly opposite the four data pins of the integrated circuits 502 on the first side of the printed circuit board 504. Thus, the data pins of the integrated circuits on the opposite sides are serviced by the same signal traces using a via between the two sides for each signal trace.

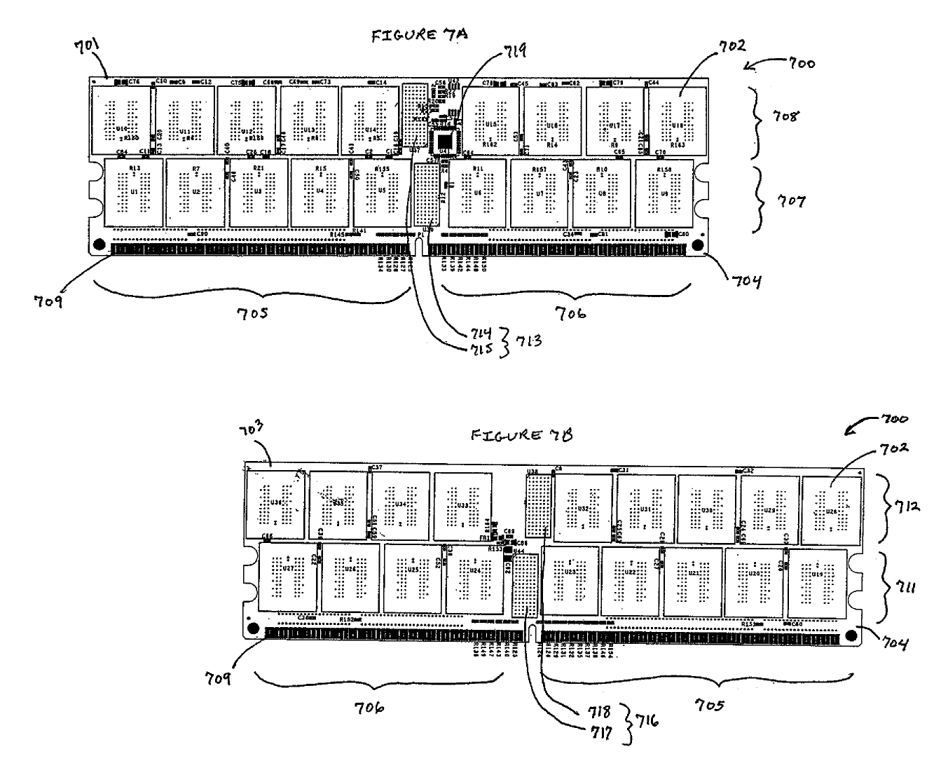

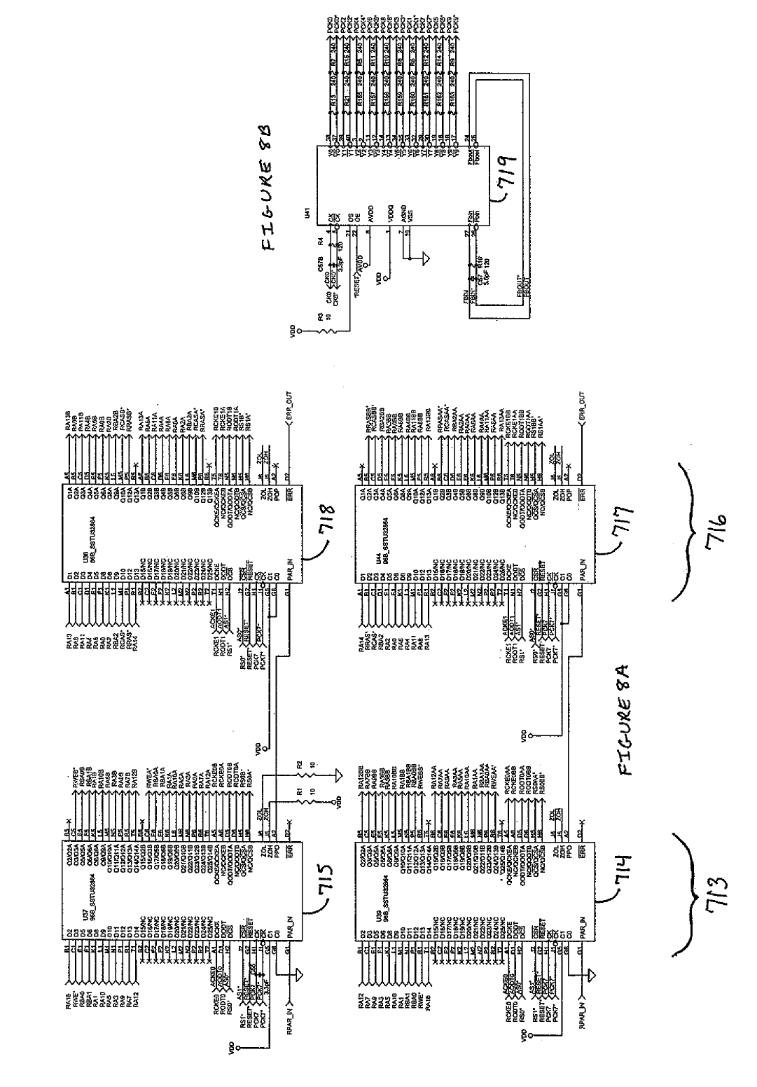

FIGURES 7A and 7B illustrate a first side and an second side, respectively, of another embodiment of a non-bilaterally symmetric memory module 700 utilizing DDR2 SDRAM integrated circuits 702. The memory module 700 has a height H of approximately one-and-one-half (1½) inches (38 mm) and a width W of approximately five-and-one-fourth (5¼) inches (133.35 mm). The module 700 comprises a first row 707 of integrated circuits 702 and a second row 708 of integrated circuits 702 on a first side 701 of a printed circuit board 704 and a third row 711 of integrated circuits 702 and a fourth row 712 of integrated circuits on the second side 703 of the printed circuit board 704. Each of the first row 707, the second row 708, the third row 711, and the fourth row 712 has five integrated circuits 702 on a first lateral portion 705 of the printed circuit board 704 and four integrated circuits 702 on a second lateral portion 706 of the printed circuit board 704. The integrated circuits 702 of the first row 707 and the third row 711 have a first orientation direction and the integrated circuits 702 of the second row 708 and the fourth row 712 have a second orientation direction which is 180 degrees relative to the first orientation direction, as shown by the BGA of the integrated circuits 702. The printed circuit board 704 has an edge connector 709 along one edge which provides electrical connections of the memory module 700 to the computer system.

The first side 701 has a first addressing register 713 comprising a pair of register integrated circuits 714, 715 and the second side 703 has a second addressing register 716 comprising a pair of register integrated circuits 717, 718. The first side 701 also comprises a clock integrated circuit 719. The integrated circuits 702 of the first row 707 and the second row 708 are offset laterally relative to one another, thereby accommodating the first addresssing register 713 and the clock integrated circuit 719 on the first side 701. Similarly, the integrated circuits 702 of the third row 711 and the fourth row 712 are offset laterally relative to one another, thereby accommodating the second addressing register 716.

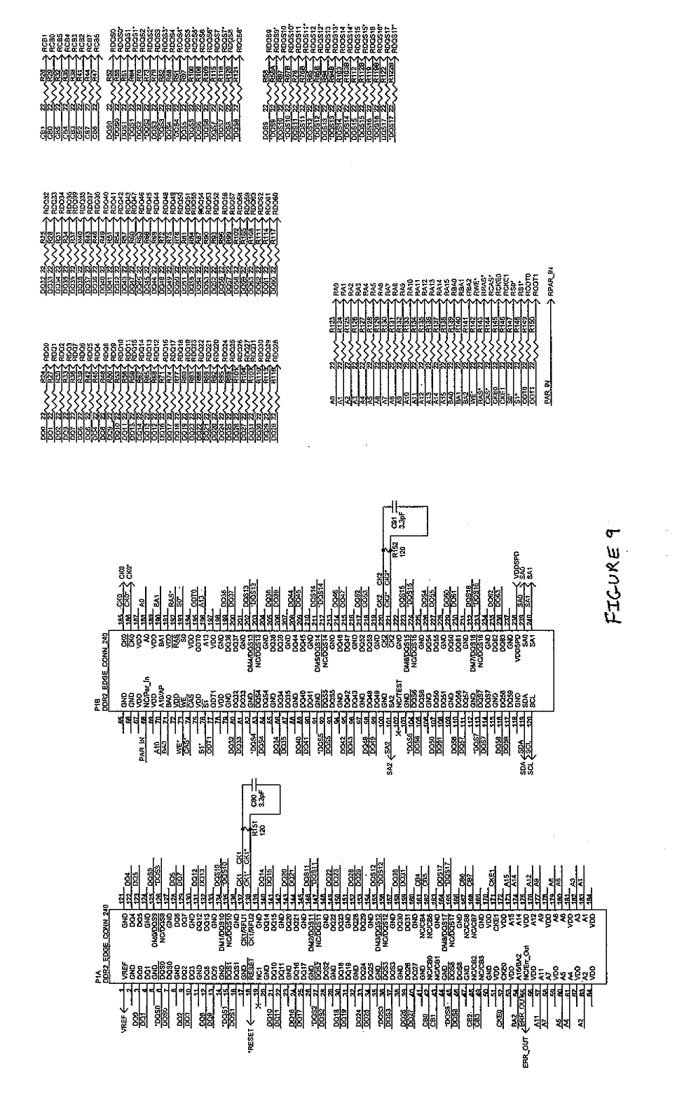

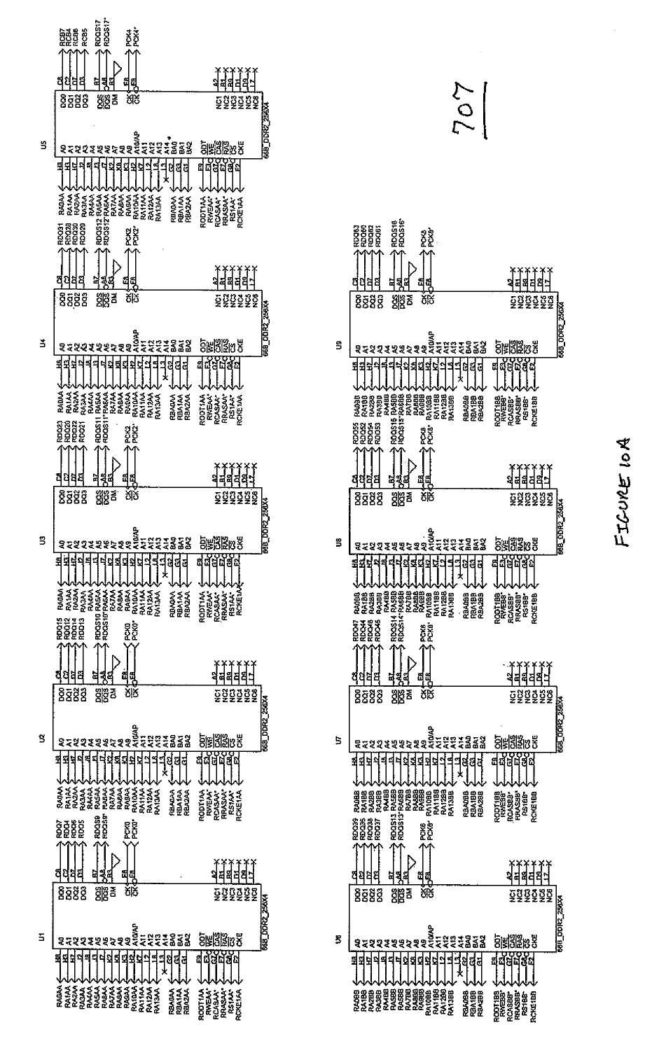

FIGURE 8A illustrates an exemplary connection scheme for the addressing registers 713, 716 of the embodiment of FIGURES 7A and 7B. FIGURE 8B illustrates an exemplary connection scheme for the clock integrated circuit 719 of the embodiment of FIGURES 7A and 7B. FIGURE 9 illustrates an exemplary connection scheme for the edge connector 709 of the printed circuit board 704. The connection scheme for the addressing registers 713, 716, the clock 719, and the edge connector 709 of a particular embodiment depends on the integrated circuits used, the memory integrated circuits 702 used, and the desired geometry and layout of the printed circuit board 704.

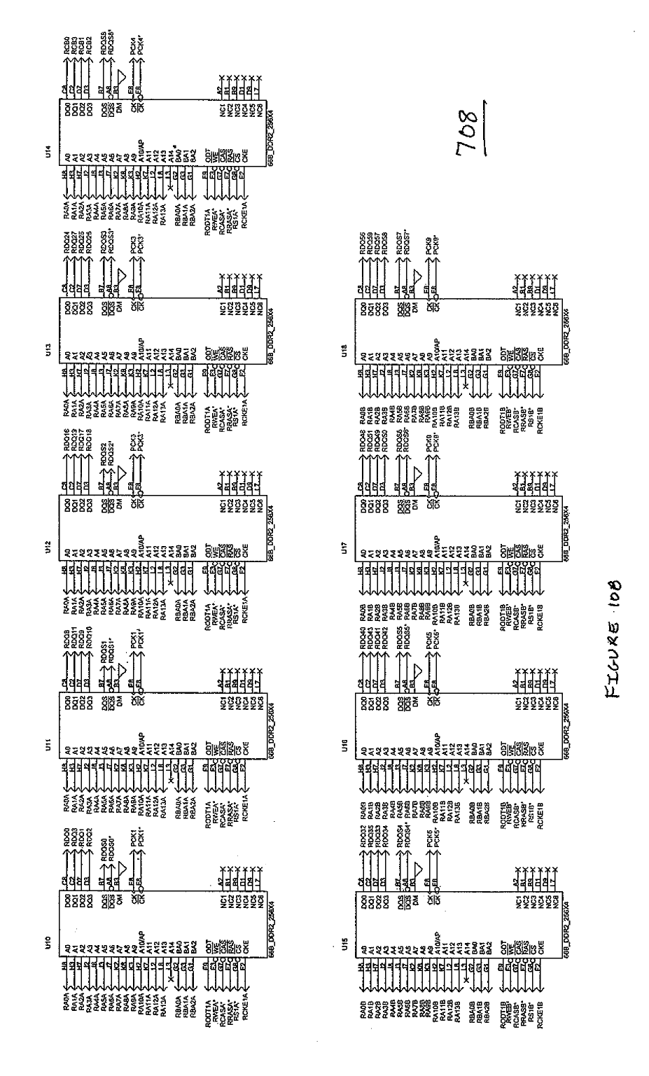

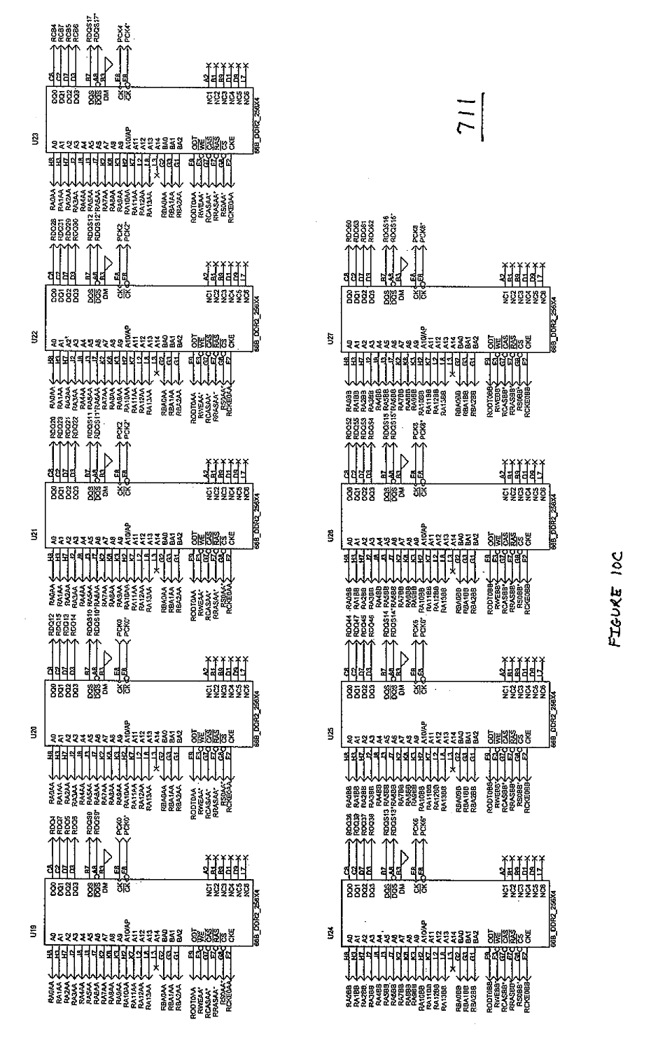

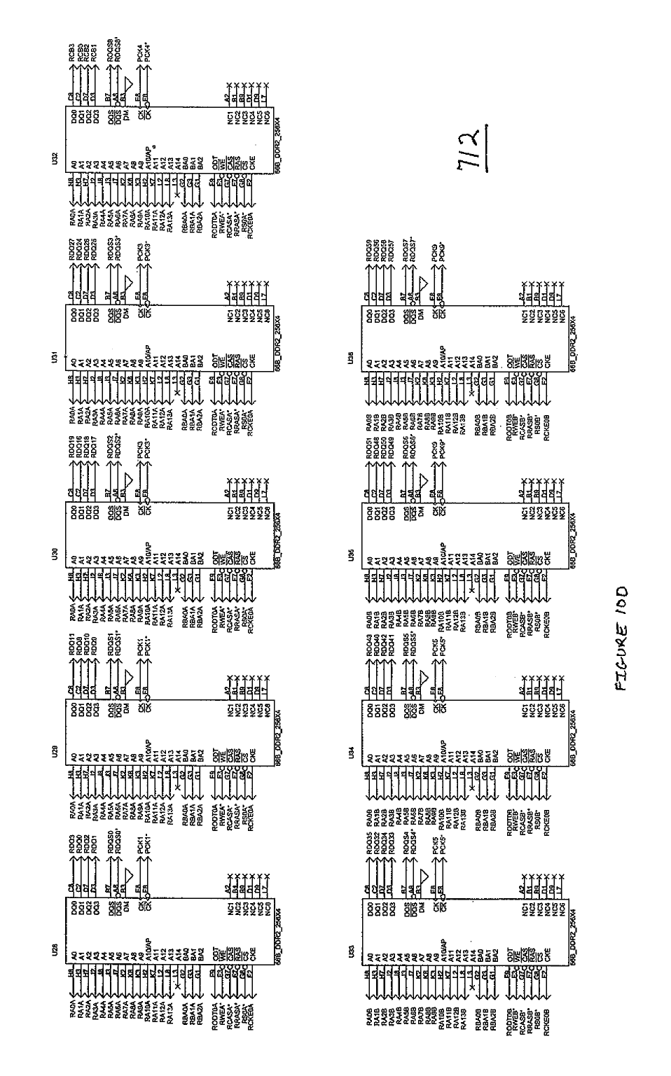

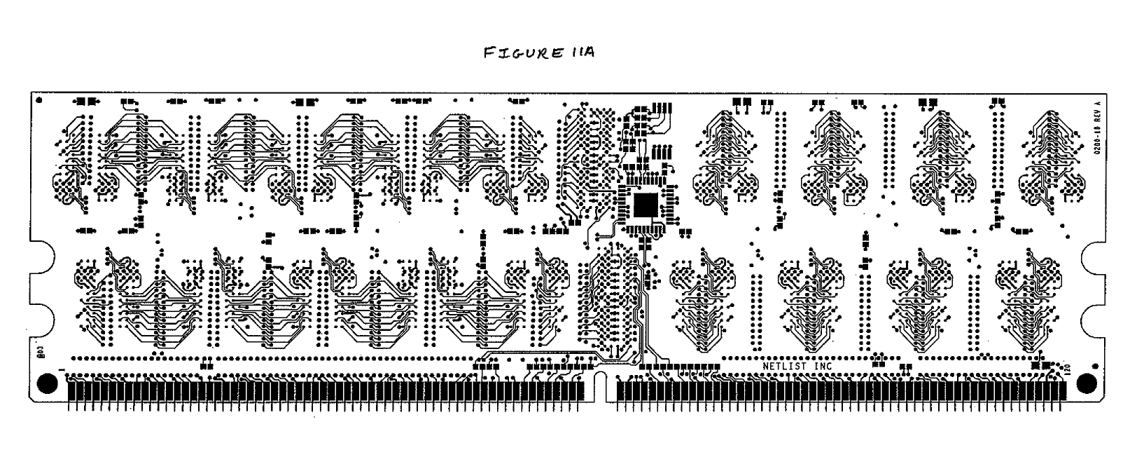

FIGURES 10A-10D illustrate an exemplary connection scheme for the integrated circuits 702 of the first row 707, the second row 708, the third row 711, and the fourth row 712, respectively, for a 1-Gb memory module using DDR2 SDRAM integrated circuits 702. The connection scheme of FIGURES 10A-10D is consistent with those of FIGURES 8A, 8B, and 9 for the addressing registers 713, 716, the clock 719, and the edge connector 709.

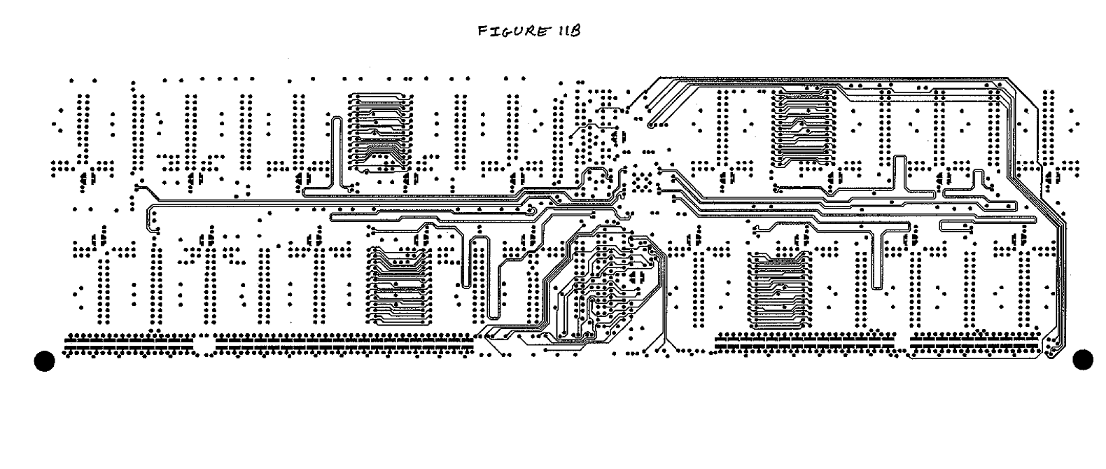

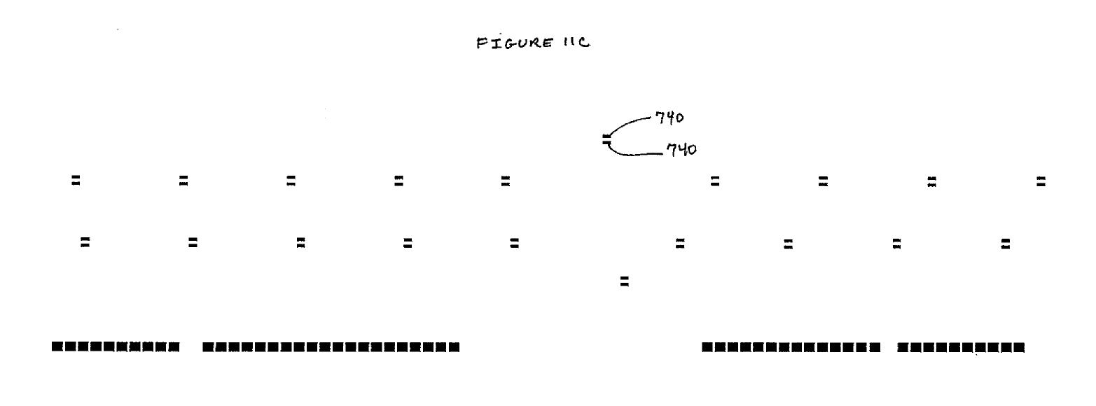

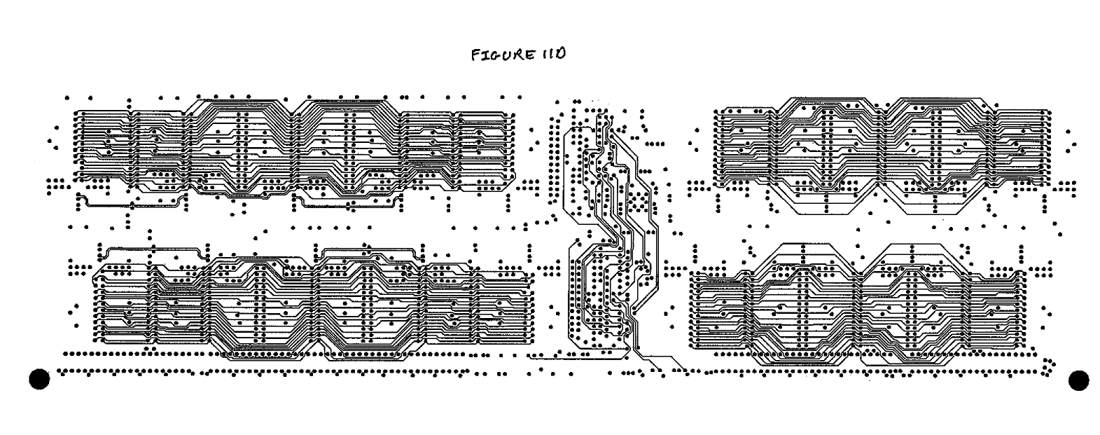

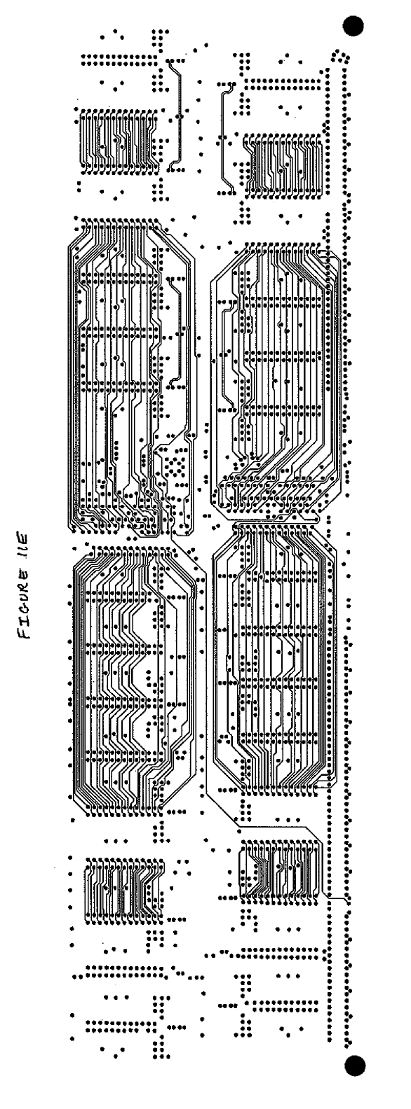

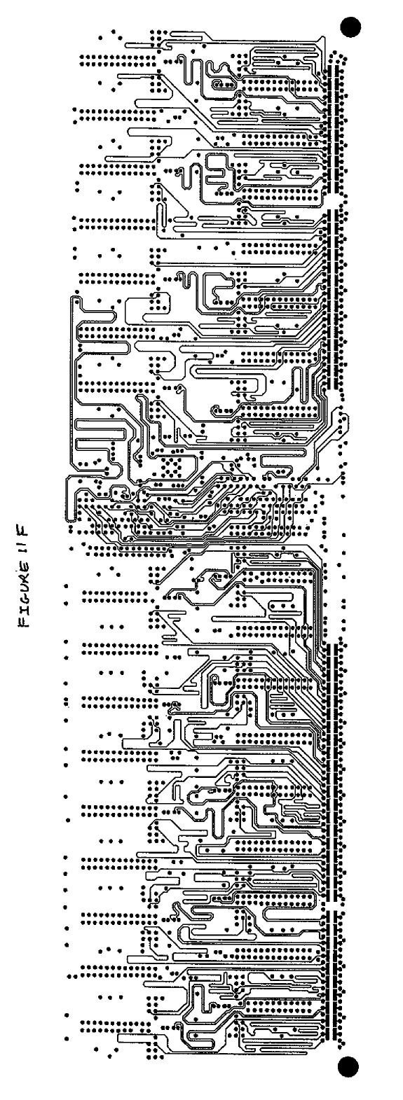

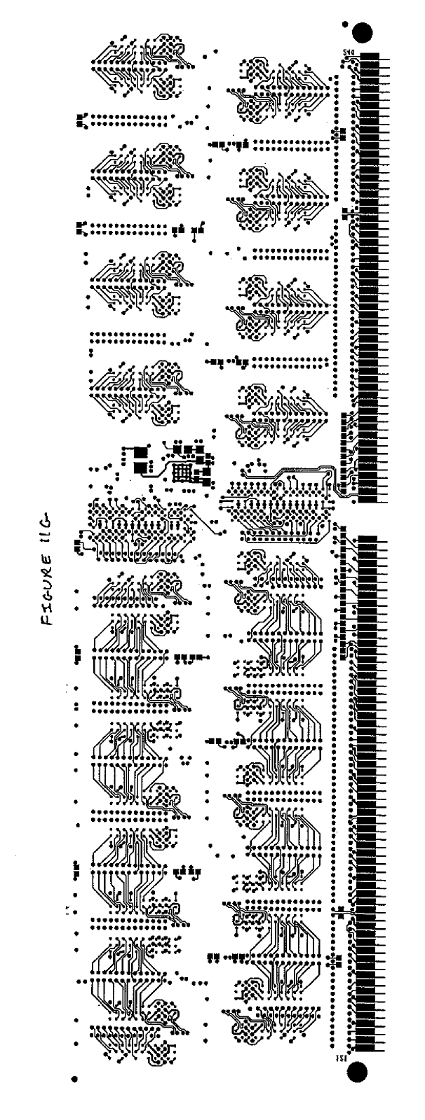

FIGURES 11A-11G illustrate exemplary routing diagrams for a series of conductive layers of the printed circuit board 704 for a 1-Gb memory module using DDR2 SDRAM integrated circuits. Electrical connections between the layers are made by conductive vias. As described above, the different orientation directions of the integrated circuits 702 of the first row 707 and of the second row 708 allow the traces on the signal layer of the memory module 700 to be placed such that the trace lengths to the data pins of the integrated circuits 702 in the two rows have substantially the same length (to within approximately 10% of the total trace length). In such embodiments, the substantial equality of trace lengths is achieved without requiring the addition of repetitious back-and-forth (i.e., serpentine) trace portions (see, e.g., FIGURE 11F).

In addition, the exemplary routing diagram of FIGURES 11A-11G satisfy the timing requirements for the memory module 700 by connecting the integrated circuits 702 to the addressing registers 713, 716 using traces of substantially similar lengths. For example, each integrated circuit 702 of the first row 707 on the first lateral portion 705 is electrically connected to the first register integrated circuit 714 of the first addressing register 713 by traces that are of substantially the same lengths. Similarly, each integrated circuit 702 of the first row 707 on the second lateral portion 706 is electrically connected to the first register integrated circuit 717 of the second addressing register 716 by traces that are of substantially the same lengths. The signal paths for the address signals to the integrated circuits 702 are advantageously routed among the various layers of the printed circuit board 704 so that the signal paths are of substantially the same lengths.

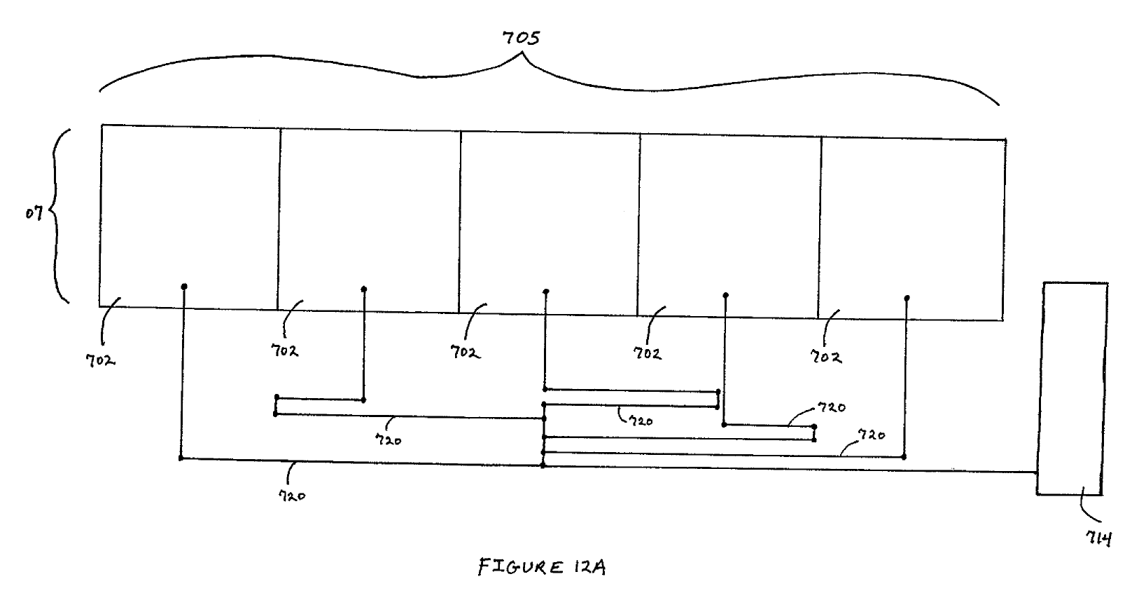

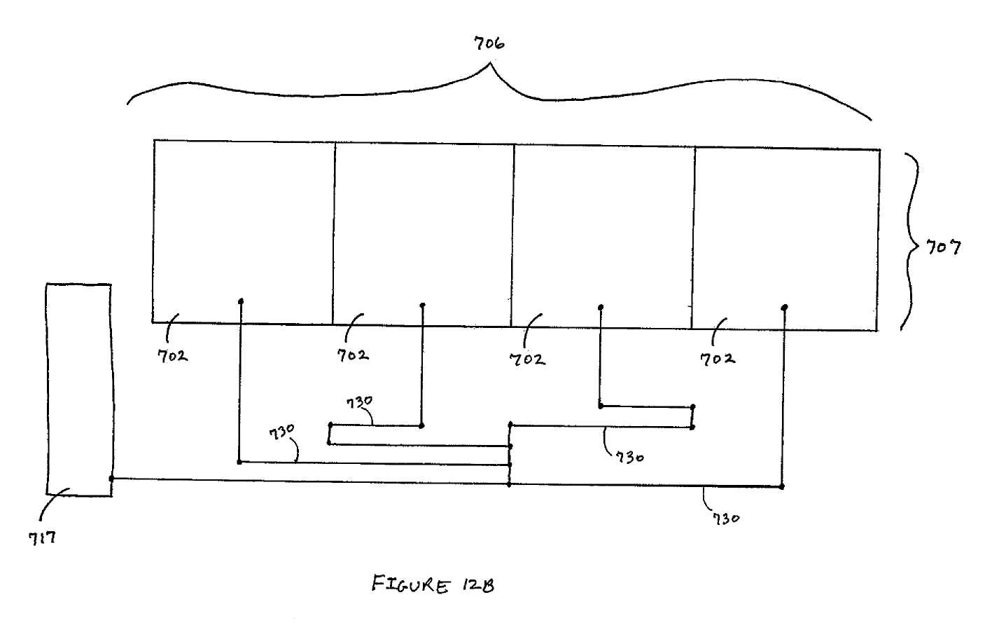

FIGURE 12A schematically illustrates the signal paths 720 for a selected register ball of the BGA of the integrated circuits 702 of the first row 707 on the first lateral portion 705. Each signal path 720 connects a ball of the integrated circuit 702 to a corresponding ball of the first register integrated circuit 714 of the first addressing register 713. As can be seen in FIGURE 12A, each signal path 720 has substantially the same length for each of the integrated circuits 702. Similarly, FIGURE 12B schematically illustrates the signal paths 730 from the first register integrated circuit 717 of the second addressing register 716 to the integrated circuits 702 of the first row 707 on the second lateral portion 706.

In certain embodiments, the printed circuit board 704 comprises a plurality of embedded passive components (e.g., resistors, capacitors, inductors). Previously, memory modules have utilized surface-mounted passive components (e.g., for line termination such as series damping termination or differential termination). Since these surface-mounted passive components share surface area of the printed circuit board with the memory integrated circuits, the locations of the surface-mounted passive components are often sub-optimal. Such surface-mounted passive components are typically placed whereever there is available space on the printed circuit board that is not used for memory integrated circuits.

Embodiments described herein provide for the first time memory modules with embedded passive components. Such embedded passive components can be used to solve traditional problems with resistive damping and termination, load balancing or reduction of noise due to electrical resonances, voltage decoupling to minimize perturbations in the power supply voltages, signal tuning and filtering for signal quality, or related design challenges in the design of memory modules. Such embedded passive components advantageously do not take up physical space on the surface of the printed circuit board, thereby allowing the positions of the other components to be optimized, allowing larger memory integrated circuits to be used in a fixed board space, and reducing the size of the printed circuit board. In addition, such embedded passive components can reduce the cost or complexity of manufacture of the memory module by eliminating solder connections or by eliminating the fabrication step of placing the passive components on the surface. In certain embodiments, embedded passive components can be advantagously positioned to improve signal integrity and to optimize high speed operation. For example, one advantage to using embedded passive resistors is that they can be placed near the mating connector. Embodiments utilizing embedded passive components also can provide other benefits, including, but not limited to, superior signal integrity and quality matching, simpler signal routing and layout, and more flexibility in the placement of components, as compared to traditional memory module designs. Typically, the results of using embedded passive components include a more easily manufactured memory module at a reduced cost.

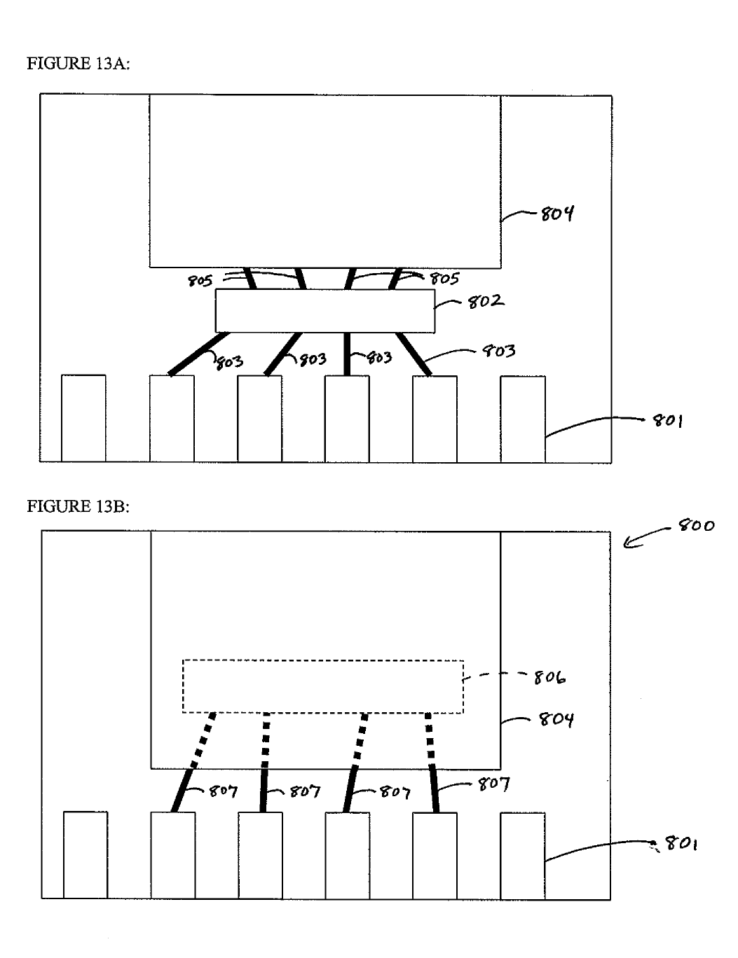

FIGURE 13A schematically illustrates an embodiment using traditional surface-mounted resistors 802 in proximity to the integrated circuit 804. The surface-mounted resistors 802 are electrically coupled to the edge connector 801 by signal lines 803 and to the integrated circuit 804 by signal lines 805. FIGURE 13B schematically illustrates an embodiment of a memory module 800 utilizing an embedded resistor 806 positioned beneath the integrated circuit 804. The embedded resistor 806 is electrically coupled to the edge connector 801 by signal lines 807 and to the integrated circuit 804 by signal lines (not shown in FIGURE 13B).

In certain embodiments, embedded resistors 806 are used for damping and termination of electrical signals, usually to prevent reflections that would compromise signal quality for the rest of the memory module or for the system into which the memory module is placed. Other uses for embedded resistors 806 include, but are not limited to, voltage dividers to create unique voltage levels not supplied from the host system, or pull-up or pull-down resistors on unused pins for safety or test functions. One advantage of using embedded resistors 806 over surface-mounted resistors 802 is that embedded resistors 806 can be located at more optimal locations on the memory module for the function that they provide.

For example, FIGURE 11C illustrates the positions of embedded resistors 740 in the exemplary routing diagrams of FIGURES 11A-11G. Such embedded resistors, as well as other embedded passive components (e.g., capacitors and inductors), can be fabricated by various techniques, including but not limited to those disclosed in the following patents assigned to Motorola, Inc. of Schaumburg, Illinois: U.S. Patent Nos. 5,912,507; 5,994,997; 6,103,134; 6,108,212; 6,130,601; 6,171,921; 6,194,990; 6,225,035; 6,229,098; 6,232,042; 6,256,866; 6,342,164; 6,349,456; and 6,440,318. Each of these patents is incorporated in its entirety by reference herein. Materials for manufacturing printed circuit boards comprising embedded passive components are available from Gould Electronics, Inc. of Eastlake, Ohio and Ohmega Technologies, Inc. of Culver City, California.

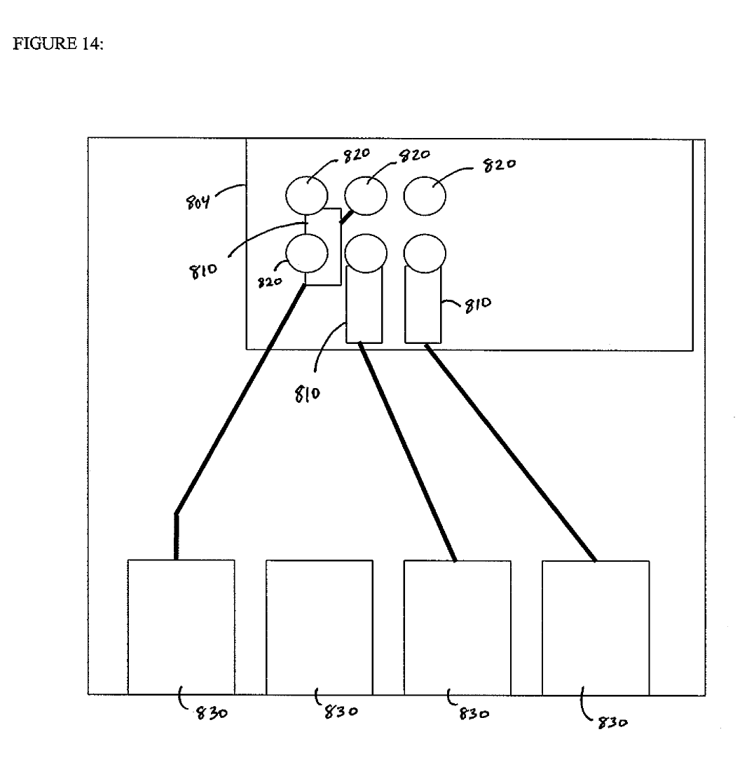

In certain embodiments, embedded resistors are used as series damping resistors located close to the pin or solder ball of the memory module device. For example, a DRAM data signal, which both sends and receives data, can benefit from having the series damping resistor close to the data pin or solder ball. As schematically illustrated in FIGURE 14, one or more embedded damping resistors 810 can be located as close as possible to the solder ball 820 along the signal path from the edge connectors 830. Since the embedded resistors 810 are on non-surface layers of the printed circuit board, they can be located directly under other solder balls 820.

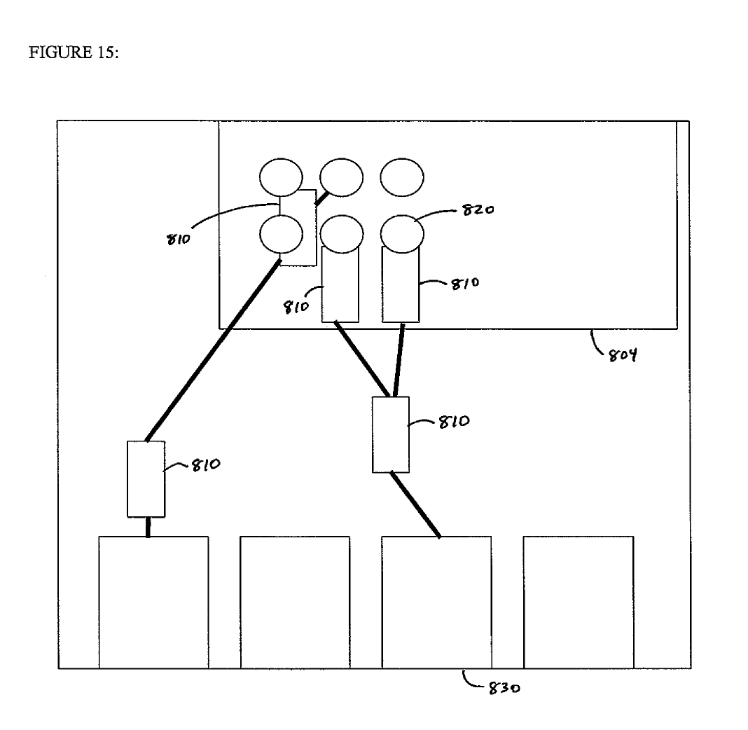

In certain embodiments, multiple embedded resistors 810 are used for line damping. Such embodiments are particularly useful when there are other design constraints that affect signal quality, such as branches in the signal path or isolation of disruptions (e.g., connectors). In such embodiments, as schematically illustrated by FIGURE 15, locating embedded resistors 810 near the point of branching, or near the contact to the connector 830, can improve the quality of signal transmission.

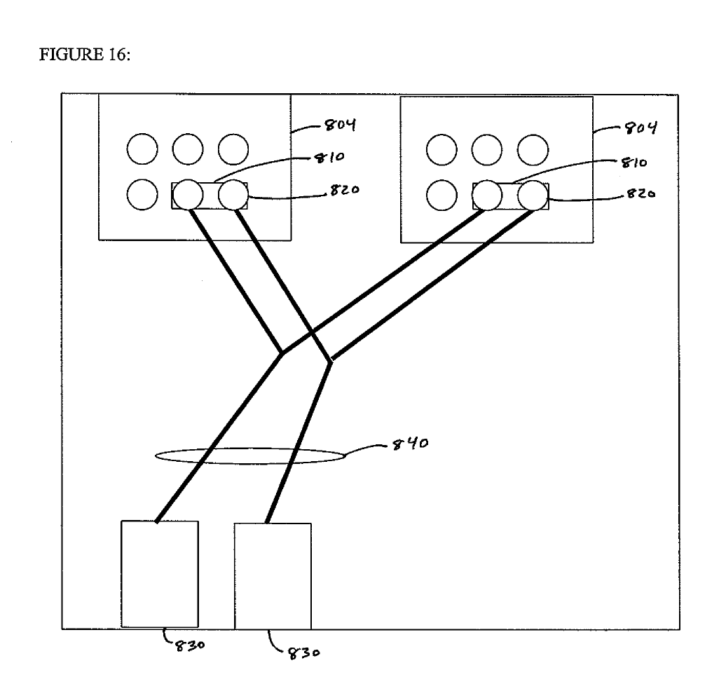

In certain embodiments, termination of a differential signal path pair 840 is managed using embedded resistors 810. As schematically illustrated by FIGURE 16, a preferred line termination for differential signal path pairs 840 is to locate the termination resistors 810 directly under the solder balls 820. Locating the termination resistors 810 at the end of each pair of signal paths reduces or eliminates the need for false termination branches from the pair (as is done using conventional surface-mounted resistors) and improves signal quality.

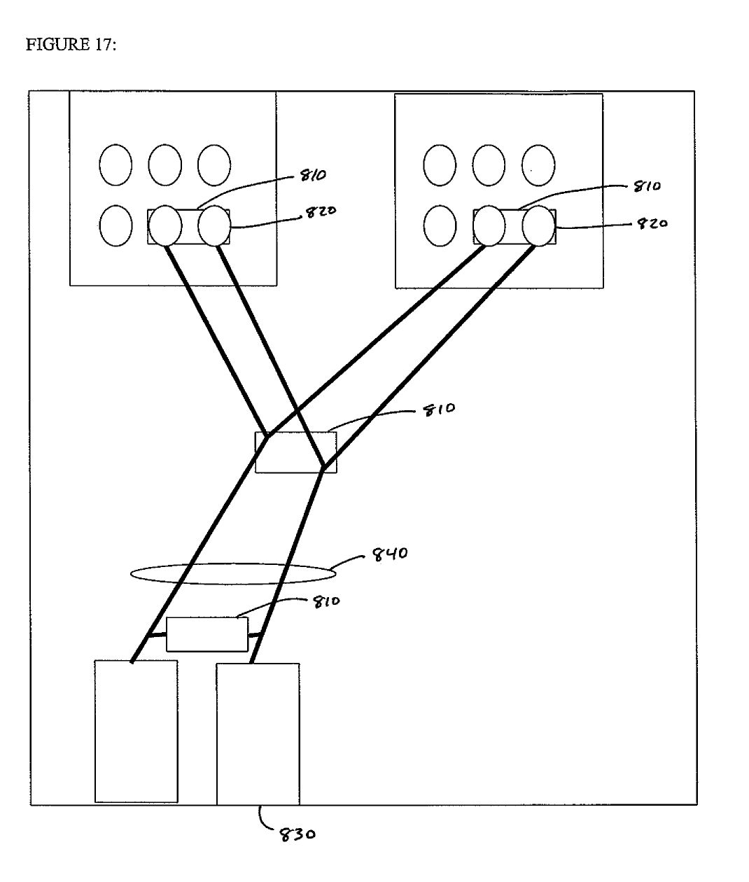

In certain embodiments, the differential signal path pair 840 is terminated with embedded resistors 810 at critical points, such as branches, in addition to the line end termination, as schematically illustrated by FIGURE 17. Such embodiments can improve signal quality by reducing effects such as reflections from other electrical subsystems, including connectors 830 and traces from the branch points.

In certain embodiments, some damping or termination embedded resistors can be incorporated in device packages. Such embodiments are preferably used if the target application characteristics are completely known in advance. Certain such embodiments can tend to increase heat problems as the termination creates thermal problems for the package.

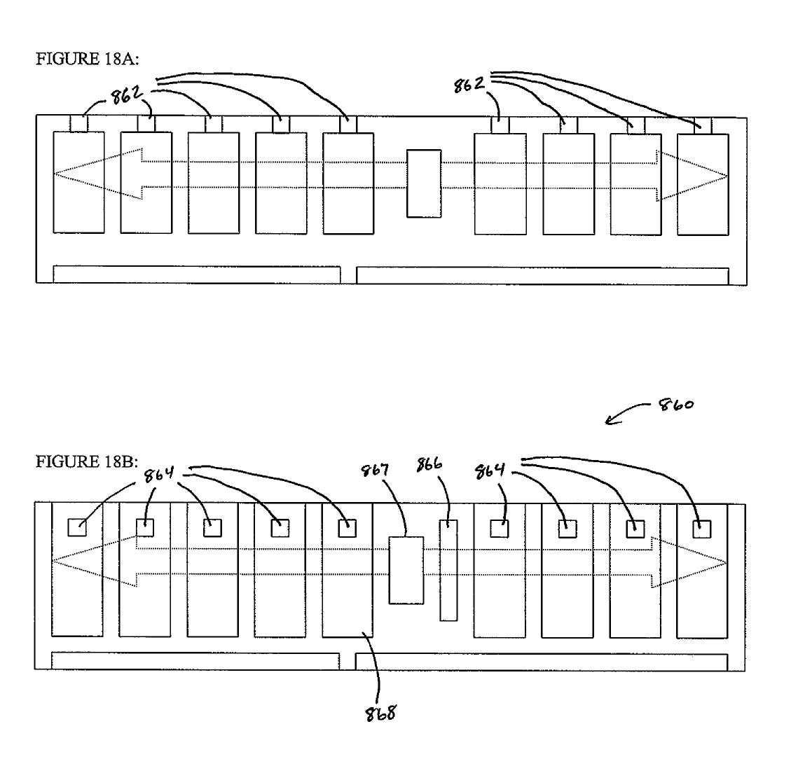

FIGURE 18A schematically illustrates an embodiment utilizing surface-mounted capacitors 862 for supply voltage decoupling without load matching. FIGURE 18B schematically illustrates an embodiment of a memory module 860 utilizing embedded decoupling capacitors 864 and embedded load matching capacitors 868. In certain embodiments, embedded capacitors are used for signal quality shaping and filtering, and voltage spike decoupling. Low-value capacitors can be used to match loading characteristics of certain signals, such as balancing the number of loads on various branches of electrical signals. They can provide test points for module validation or testing as well. In certain embodiments, higher-value capacitors can act as short-term power supplies for smoothing out spikes in supply or reference voltages caused by normal operation of the memory modules (decoupling).

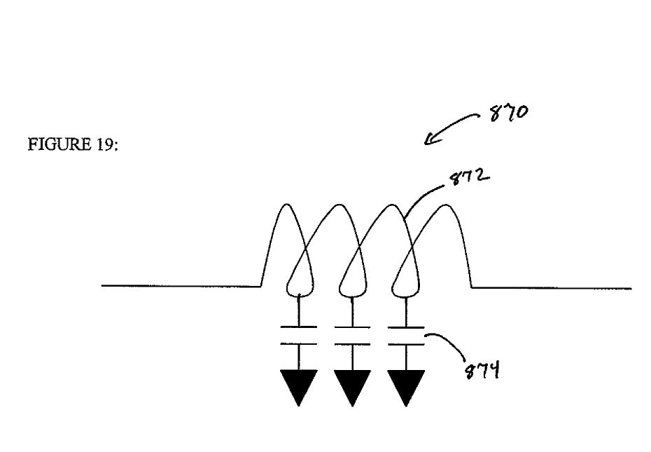

In certain embodiments, embedded inductors can be utilized to filter low frequency noise from electrical signals. In certain such embodiments, the embedded inductors can be utilized in conjunction with embedded capacitors to provide signal filtering. FIGURE 19 schematically illustrates an embodiment of an embedded flux capacitor 870 with a filtered line using discrete embedded inductors 872 and embedded capacitors 874. The embedded flux capacitor 870 utilizes the combined inductor and capacitors to create bandpass filters for specific frequency response ranges. The embedded flux capacitor 870 combines these passive devices into a single embedded structure, thereby further minimizing the area used. Such embodiments can be used to provide an embedded flux capacitor 870 on every signal line.

Although the invention has been described in terms of certain preferred embodiments, other embodiments that are apparent to those of ordinary skill in the art, including embodiments which do not provide all of the features and advantages set forth herein, are also within the scope of this invention. Accordingly, the scope of the invention is defined by the claims that follow.

1. A memory module comprising:
a printed circuit board comprising a first lateral portion and a second lateral portion;
a first plurality of memory integrated circuits identical to one another, the first plurality of memory integrated circuits positioned on the first lateral portion of the printed circuit board;
a second plurality of memory integrated circuits identical to one another and identical to the memory integrated circuits of the first plurality, the second plurality of memory integrated circuits positioned on the second lateral portion of the printed circuit board;
a first register integrated circuit coupled to the first plurality of memory integrated circuits;
a second register integrated circuit coupled to the first plurality of memory integrated circuits;
a third register integrated circuit coupled to the second plurality of memory integrated circuits; and
a fourth register integrated circuit coupled to the second plurality of memory integrated circuits.

2. The memory module of Claim 1, wherein the memory integrated circuits comprise DDR2 SDRAM integrated circuits.

3. A memory module comprising:
a generally planar printed circuit board comprising an edge, a common signal trace connector area along the edge, and a first side, the printed circuit board having a first lateral portion and a second lateral portion;
a first row of memory integrated circuits identical to one another, the first row positioned on the first side of the printed circuit board, the first row being in proximity to the common signal trace connector area, the integrated circuits of the first row having a first orientation direction, the first row having a first number of integrated circuits on the first lateral portion and a second number of integrated circuits on the second lateral portion, the first number larger than the second number;
a second row of memory integrated circuits identical to the integrated circuits of the first row, the second row positioned on the first side of the printed circuit board, the second row being located physically farther from the common signal trace connector than is the first row, the integrated circuits of the second row having a second orientation direction at a non-zero angle relative to the first orientation direction, the second row having a third number of integrated circuits on the first lateral portion and a fourth number of integrated circuits on the second lateral portion, the third number larger than the fourth number;
a first addressing register comprising two register integrated circuits, the first addressing register coupled to the integrated circuits of the first row on the first lateral portion and coupled to the integrated circuits of the second row on the first lateral portion; and
a second addressing register comprising two register integrated circuits, the second addressing register coupled to the integrated circuits of the first row on the second lateral portion and coupled to the integrated circuits of the second row on the second lateral portion.

4. The memory module of Claim 3, wherein the first row is substantially parallel to the edge.

5. The memory module of Claim 3, wherein the second row is substantially parallel to the edge.

6. The memory module of Claim 3, wherein the memory integrated circuits comprise Double Data Rate SDRAM integrated circuits.

7. The memory module of Claim 3, wherein the memory integrated circuits comprise DDR2 SDRAM integrated circuits.

8. The memory module of Claim 3, wherein the memory integrated circuits comprise ball-grid-array (BGA) SDRAM integrated circuits.

9. The memory module of Claim 3, wherein the memory integrated circuits comprise PC133 SDRAM integrated circuits.

10. The memory module of Claim 3, wherein the non-zero angle is approximately 180 degrees.

11. The memory module of Claim 3, wherein the first number equals the third number.

12. The memory module of Claim 3, wherein the second number equals the fourth number.

13. The memory module of Claim 3, wherein the first number is at least five.

14. The memory module of Claim 3, wherein the second number is at least four.

15. The memory module of Claim 3, wherein the memory module further comprises:
a first plurality of data lines electrically connecting data pins of the first row of integrated circuits to the common signal trace connector area; and
a second plurality of data lines electrically connecting data pins of the second row of integrated circuits to the common signal trace connector area, whereby lengths of corresponding data lines of the first plurality of data lines and the second plurality of data lines are substantially the same.

16. The memory module of Claim 3, wherein the first addressing register and the second addressing register access data bits of non-contiguous subsets of a data word.

17. The memory module of Claim 16, wherein:
the first addressing register accesses data bits 0 to 3, 8 to 11, 16 to 19, and 24 to 27; and
the second addressing register accesses data bits 4 to 7, 12 to 15, 20 to 23, and 28 to 31.

18. The memory module of Claim 3, wherein the memory module has a height of approximately one-and-one-half (1½) inches and a width of approximately five-and-one-fourth (5¼) inches.

19. The memory module of Claim 3, further comprising:
a third row of memory integrated circuits identical to the integrated circuits of the first row, the third row positioned on a second side of the printed circuit board, the third row being in proximity to the common signal trace connector area, the integrated circuits of the third row having a third orientation direction, the first row and the third row having the same number of integrated circuits on the first lateral portion and the first row and the third row having the same number of integrated circuits on the second lateral portion; and
a fourth row of memory integrated circuits identical to the integrated circuits of the first row, the fourth row positioned on the second side of the printed circuit board, the fourth row being located physically farther from the common signal trace connector than is the third row, the integrated circuits of the fourth row having a fourth orientation direction at a non-zero angle relative to the third orientation direction, the second row and the fourth row having the same number of integrated circuits on the first lateral portion and the second row and the fourth row having the same number of integrated circuits on the second lateral portion,
wherein the first addressing register is coupled to the integrated circuits of the third row on the first lateral half and to the integrated circuits of the fourth row on the first lateral half and the second addressing register is coupled to the integrated circuits of the third row on the second lateral half and to the integrated circuits of the fourth row on the second lateral half.

20. The memory module of Claim 19, wherein the third orientation direction is substantially the same as the first orientation direction, and the fourth orientation direction is substantially the same as the second orientation direction.

21. A memory module comprising:
a generally planar printed circuit board comprising an edge, a common signal trace connector area along the edge, and a first side, the printed circuit board having a first lateral portion and a second lateral portion;
a first row of memory integrated circuits identical to one another, the first row positioned on the first side of the printed circuit board, the first row being in proximity to the common signal trace connector area, the integrated circuits of the first row having a first orientation direction, the first row having a first number of integrated circuits on the first lateral portion and a second number of integrated circuits on the second lateral portion, the first number larger than the second number;
a second row of memory integrated circuits identical to the integrated circuits of the first row, the second row positioned on the first side of the printed circuit board, the second row being located physically farther from the common signal trace connector than is the first row, the integrated circuits of the second row having a second orientation direction at a non-zero angle relative to the first orientation direction, the second row having a third number of integrated circuits on the first lateral portion and a fourth number of integrated circuits on the second lateral portion, the third number larger than the fourth number;
a first addressing register comprising at least one register integrated circuit, the first addressing register coupled to the integrated circuits of the first row on the first lateral portion and coupled to the integrated circuits of the second row on the first lateral portion; and
a second addressing register comprising at least one register integrated circuit, the second addressing register coupled to the integrated circuits of the first row on the second lateral portion and coupled to the integrated circuits of the second row on the second lateral portion.

22. The memory module of Claim 21, wherein the first addressing register comprises at least two register integrated circuits.

23. The memory module of Claim 21, wherein the second addressing register comprises at least two register integrated circuits.

24. A one-Gigabyte capacity memory module comprising 36 integrated circuits of type 256-Megabit SDRAM organized as 64 Meg by 4 bits in a ball grid array (BGA) package, the memory module being approximately five-and-one-fourth inches wide by approximately one-and-one-half inches high, the integrated circuits arranged in two rows on each of two surfaces of a printed circuit board.

25. The memory module of Claim 24, wherein the integrated circuits are DDR2 SDRAM.

26. A two-Gigabyte capacity memory module comprising 36 integrated circuits of type 512-Megabit SDRAM organized as 128 Meg by 4 bits in a ball grid array (BGA) package, the memory module being approximately five-and-one-fourth inches wide by approximately one-and-one-half inches high, the integrated circuits arranged in two rows on each of two surfaces of a printed circuit board.

27. The memory module of Claim 26, wherein the integrated circuits are DDR2 SDRAM.

28. A four-Gigabyte capacity memory module comprising 36 integrated circuits of type 1024-Megabit SDRAM organized as 256 Meg by 4 bits in a ball grid array (BGA) package, the memory module being approximately five-and-one-fourth inches wide by approximately one-and-one-half inches high, the integrated circuits arranged in two rows on each of two surfaces of a printed circuit board.

29. The memory module of Claim 28, wherein the integrated circuits are DDR2 SDRAM.

30. A memory module comprising:
a printed circuit board having a plurality of signal lines;
a plurality of memory integrated circuit packages mounted on a first face of the printed circuit board, each memory integrated circuit package having a plurality of conductive contacts; and
a plurality of passive components electrically coupled to the plurality of conductive contacts and the plurality of signal lines, the plurality of passive components embedded within the printed circuit board.

31. The memory module of Claim 30, wherein the embedded passive components comprise embedded resistors.

32. The memory module of Claim 31, wherein the embedded resistors comprise series damping resistors positioned in proximity to corresponding conductive contacts of the memory integrated circuit packages.

33. The memory module of Claim 32, wherein the series damping resistors are positioned directly under the corresponding conductive contacts of the memory integrated circuit packages.

34. The memory module of Claim 31, wherein the embedded resistors comprise line damping resistors positioned in proximity to corresponding branching points of the signal lines.

35. The memory module of Claim 31, wherein the printed circuit board comprises an edge connector comprising a plurality of edge connections, and wherein the embedded resistors comprise line damping resistors positioned in proximity to corresponding edge connections of the edge connector.

36. The memory module of Claim 31, wherein the signal lines comprise differential signal path pairs, and wherein the embedded resistors comprise termination resistors positioned at an end of each signal path pair.

37. The memory module of Claim 36, wherein the embedded resistors further comprise termination resistors positioned at branches of the signal path pairs.

38. A four-Gigabyte capacity memory module comprising 36 integrated circuits of type 1-Gigabit SDRAM organized as 256 Meg by 4 bits in a Thin Small Outline Package (TSOP), the memory module having an approximate width of 5.25 inches and an approximate height of 2.05 inches.

39.The memory module of Claim 31, wherein the embedded resistors comprise pull-up or pull-down resistors.

40.The memory module of Claim 31, wherein the embedded resistors comprises voltage dividers to create voltage levels not supplied to the memory module from a host system.

41.The memory module of Claim 30, wherein the embedded passive components comprise embedded capacitors.

42.The memory module of Claim 41, wherein the embedded capacitors comprise decoupling capacitors.

43.The memory module of Claim 41, wherein the embedded capacitors comprise load matching capacitors.

44.The memory module of Claim 41, wherein the embedded capacitors comprise capacitors adapted for signal quality shaping and filtering.

45.The memory module of Claim 41, wherein the embedded capacitors comprise capacitors adapted for voltage spike decoupling.

46.The memory module of Claim 41, wherein the embedded capacitors comprise capacitors adapted to match loading characteristics of selected signals.

47.The memory module of Claim 41, wherein the embedded capacitors comprise capacitors adapted to smooth out voltage spikes by providing short-term power.

48.The memory module of Claim 30, wherein the embedded passive components comprise embedded inductors.

49.The memory module of Claim 48, wherein the embedded inductors are adapted to filter low frequency noise from electrical signals.

50.The memory module of Claim 30, wherein the embedded passive components comprise embedded capacitors and an embedded inductor, the embedded capacitors coupled to the embedded inductor to provide an embedded flux capacitor.

51.The memory module of Claim 50, wherein the embedded flux capacitor is adapted to provide a bandpass filter for a selected frequency response range.

52.A memory module comprising:
a printed circuit board comprising a first portion and a second portion;
a first plurality of memory integrated circuits identical to one another, the first plurality of memory integrated circuits positioned on the first portion of the printed circuit board;
a second plurality of memory integrated circuits identical to one another and identical to the memory integrated circuits of the first plurality, the second plurality of memory integrated circuits positioned on the second portion of the printed circuit board;
a first register integrated circuit coupled to the first plurality of memory integrated circuits;
a second register integrated circuit coupled to the first plurality of memory integrated circuits;
a third register integrated circuit coupled to the second plurality of memory integrated circuits; and
a fourth register integrated circuit coupled to the second plurality of memory integrated circuits.

53.The memory module of Claim 52, wherein the memory integrated circuits comprise DDR2 SDRAM integrated circuits.

54.The memory module of Claim 52, wherein the memory integrated circuits comprise Double Data Rate SDRAM integrated circuits.

55.The memory module of Claim 52, wherein the memory integrated circuits comprise ball-grid-array (BGA) SDRAM integrated circuits.

56.The memory module of Claim 52, wherein the memory integrated circuits comprise PC133 SDRAM integrated circuits.
